(19) United States
(12) Patent Application Publication
(10) Pub. No.: US 2026/0040520 A1
(43) Pub. Date: Feb. 5, 2026

(54) NANOSTRUCTURE FIELD-EFFECT TRANSISTOR DEVICE AND METHODS OF FORMING

(71) Applicant: Taiwan Semiconductor Manufacturing Co., Ltd., Hsinchu (TW)

(72) Inventors: Yi-Feng Ting, Taipei City (TW); Feng-Ming Chang, Zhubei City (TW)

(21) Appl. No.: 18/793,341

(22) Filed: Aug. 2, 2024

(51) Int. Cl. H10B 10/00; H01L 29/06; H01L 29/423; H01L 29/66; H01L 29/775; H01L 29/786

(52) U.S. Cl. CPC H10B 10/125; H10D 30/014; H10D 30/43; H10D 30/6733; H10D 30/6735; H10D 30/6757; H10D 62/121; H10D 64/017

(57) ABSTRACT

A memory device includes: a substrate; and a seven-transistor memory cell including: a first fin and a second fin, where the first fin is narrower than the second fin; a first gate structure, a second gate structure, a third gate structure, a fourth gate structure, and a fifth gate structure, where the second and third gate structures are between the first and the fourth gate structures, where the fourth and the fifth gate structures extend along a same line, where in a top view, the first and the fourth gate structures overlap the first fin, the second and the third gate structures overlap the first and the second fins, and the fifth gate structure overlaps the second fin; p-type source/drain regions over the first fin; and n-type source/drain regions over the second fin.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A-5C, 6A-6C, 7A-7C, 8A-8C, 9A-9C, 10A-10C, 11A-11C, 12A-12C, 13A, 13B, 14A, 14B, 15A, 15B, 16A, 16B, 17A, 17B, 18A, 18B, 19A-19H, 20A, and 20B are various views of a nanostructure field-effect transistor (NSFET) device at various stages of manufacturing, in accordance with an embodiment.

FIG. 21 illustrates a circuit diagram of a seven-transistor (7T) memory cell, in an embodiment.

FIGS. 22A-22E and 23 are various views of a nanostructure field-effect transistor (NSFET) device at various stages of manufacturing, in accordance with another embodiment.

FIGS. 24A and 24B together illustrate a flow chart of a method of forming a seven-transistor (7T) memory cell of a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

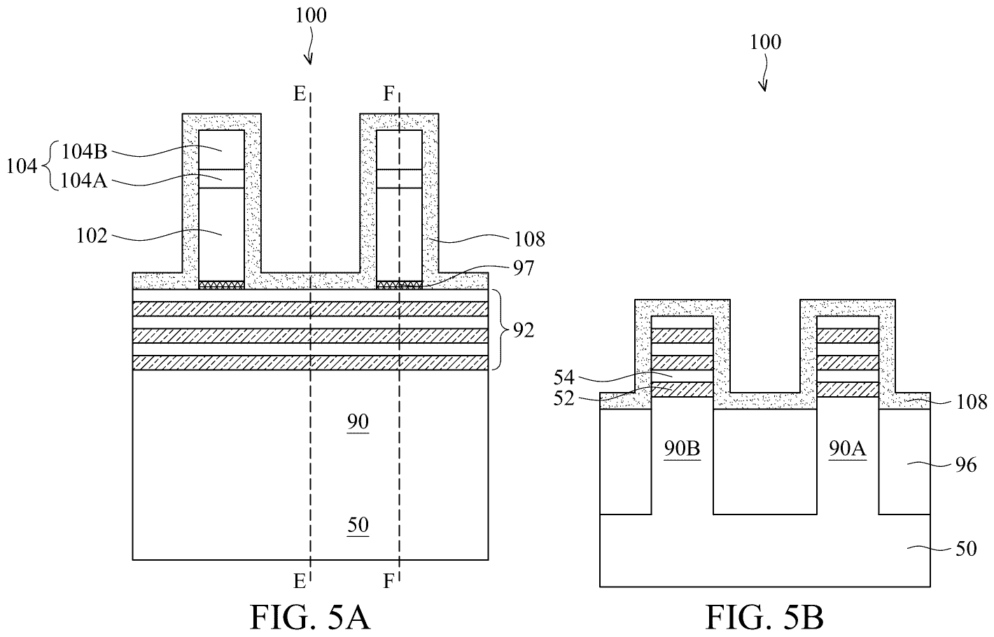

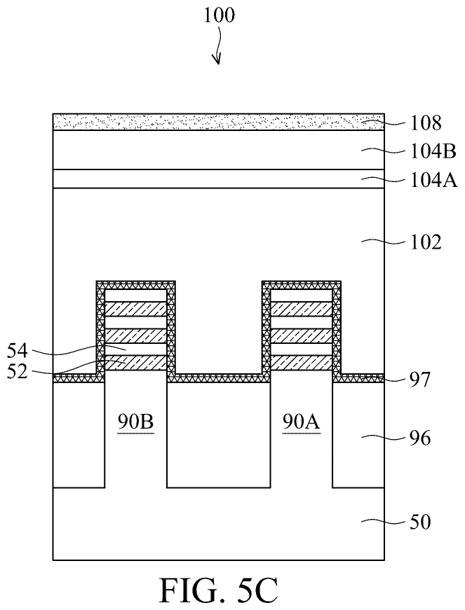

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numeral in different figures refer to the same or similar component formed by a same or similar formation process using a same or similar material(s). In addition, figures with the same numeral but different alphabets (e.g., FIGS. 5A-5C) illustrate different views of the device at the same stage of processing.

In some embodiments, during the manufacturing of the nanostructure field-effect transistors (NSFETs) of a 7T memory cell, a Disposable Oxide Interposer (DOI) process is used. The DOI process involves the use of a sacrificial material, such as silicon dioxide (SiO₂), silicon oxynitride (SiON), aluminum oxide (Al₂O₃), or the like, to replace a first semiconductor material (e.g., SiGe) in a layer stack that comprises alternating layers of the first semiconductor material and a second semiconductor material (e.g. Si). This substitution is advantageous as it reduces the intermixing of silicon and germanium and provides high etching selectivity between the sacrificial material and the second semiconductor material. As a result, the dimension of the second semiconductor material, which forms the channel regions of the NFFETs in subsequent processing, is preserved, which allows for improved driving current and less electrical resistance of the channel regions. The use the DOI process allows for flexible choice for the location of the read transistor RGP in the 7T memory cell. In an embodiment, the read transistor RGP is formed over the n-type fin as an n-type NSFET, and the write transistors WPG1 and WPG2 of the 7T memory cell are formed over the p-type fin as p-type NSFETs. The disclosed design of 7T memory cell provides strong read capability for the 7T memory cell while still offers good write capability for the 7T memory cell, due to the improved performance of the p-type NSFETs made possible by the DOI process.

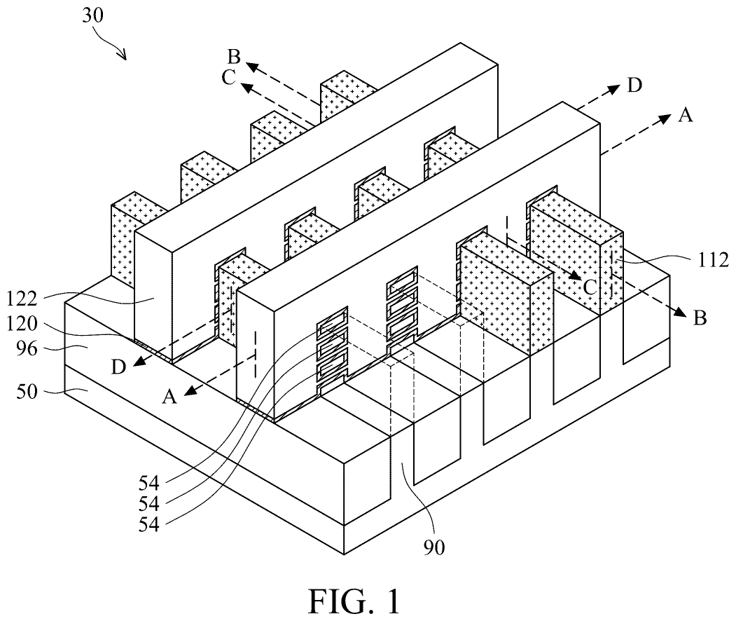

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures may refer to these reference cross-sections for clarity.

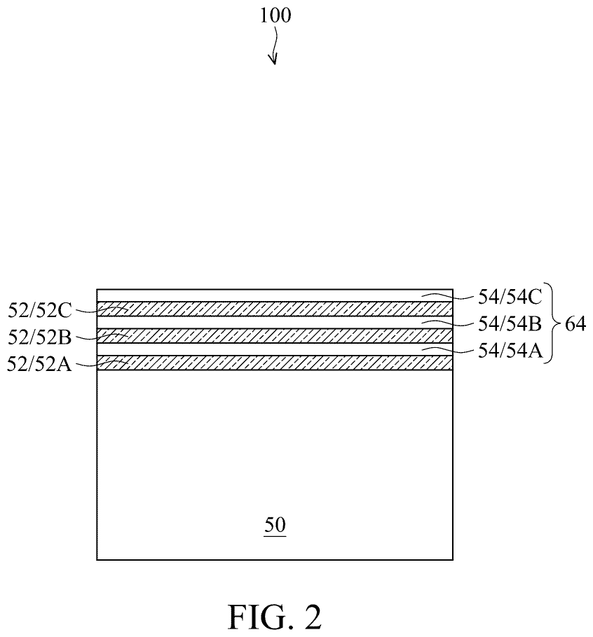

FIGS. 2, 3A, 3B, 4A, 4B, 5A-5C, 6A-6C, 7A-7C, 8A-8C, 9A-9C, 10A-10C, 11A-11C, 12A-12C, 13A, 13B, 14A, 14B, 15A, 15B, 16A, 16B, 17A, 17B, 18A, 18B, 19A-19H, 20A, and 20B are various views (e.g., cross-sectional views, top views) of a portion of a nanostructure field-effect transistor (NSFET) device 100 at various stages of manufacturing, in accordance with an embodiment. In the illustrated embodiment, the NSFET device 100 is a memory device, such as a static random-access memory (SRAM) device with seven-transistor (7T) SRAM memory cells. The 7T SRAM memory cells may also be referred to as 7T memory cells for short herein.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is a first type of epitaxial material, such as silicon germanium (SiₓGe₁₋ₓ, where x can be in the range of 0 to 1), and the second semiconductor material 54 is a second type of epitaxial material, such as silicon. The multi-layer stack 64 (which may also be referred to as an epitaxial material stack) will be patterned to form channel regions of an NSFET in subsequent processing. In particular, the multi-layer stack 64 will be patterned and etched to form horizontal nanostructures (e.g., nanosheets or nanowires), with the channel regions of the resulting NSFET including multiple horizontal nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

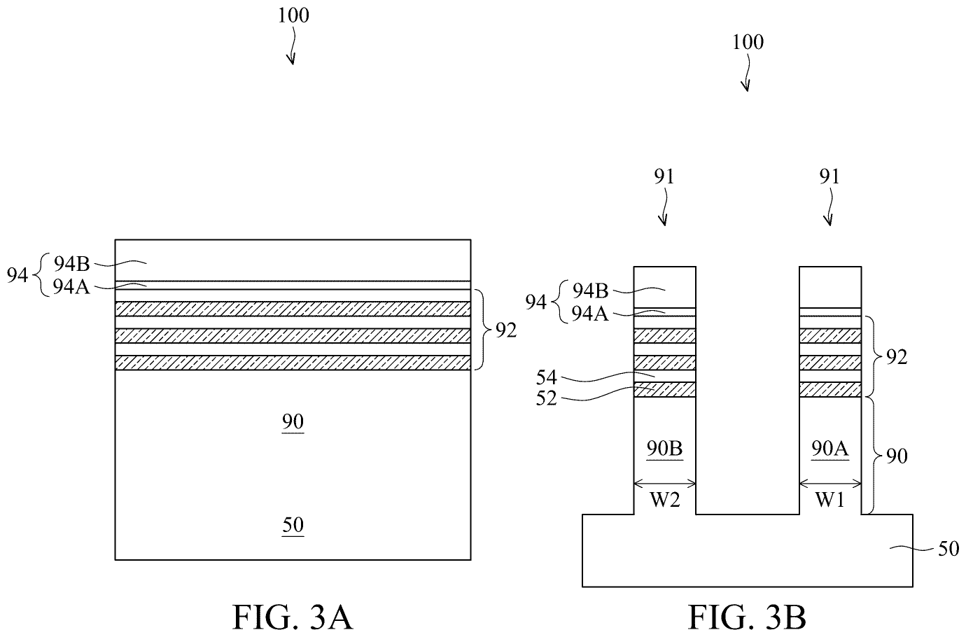

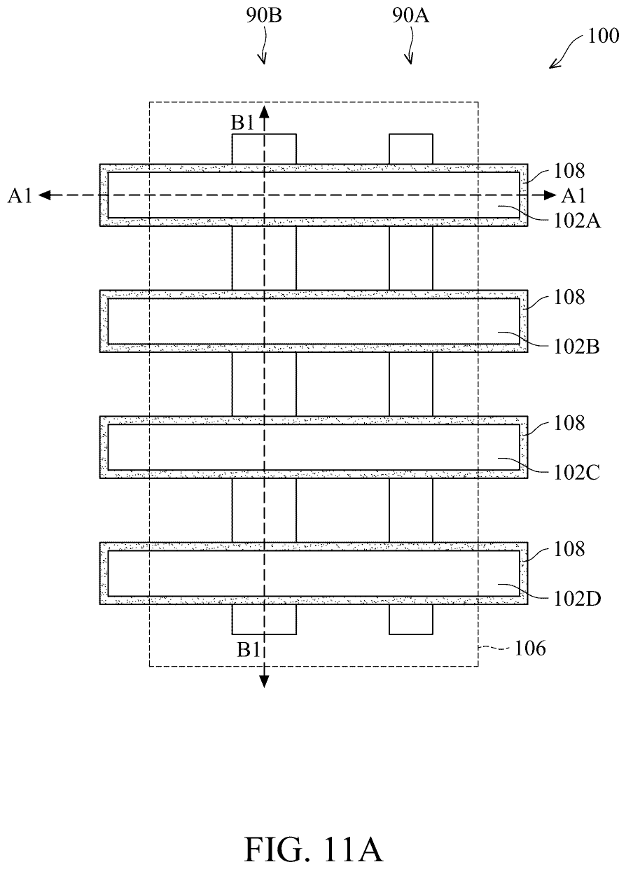

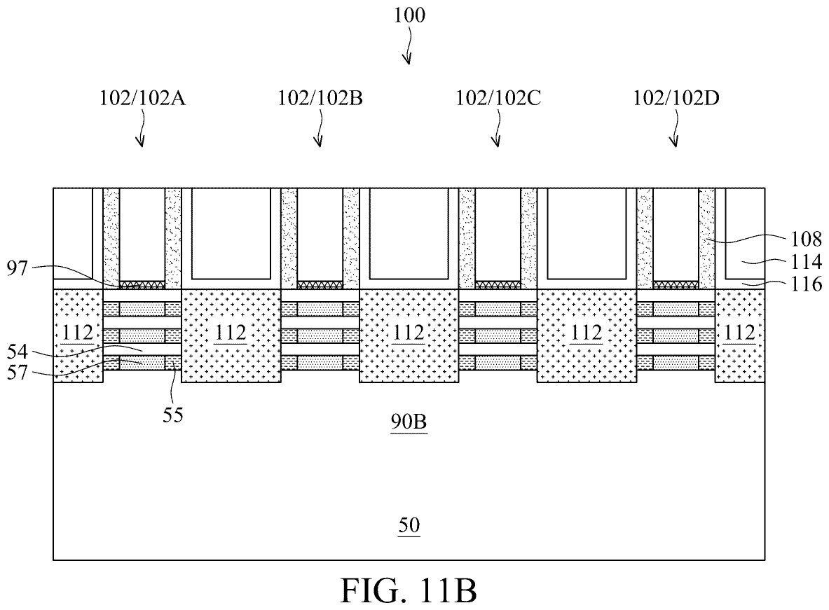

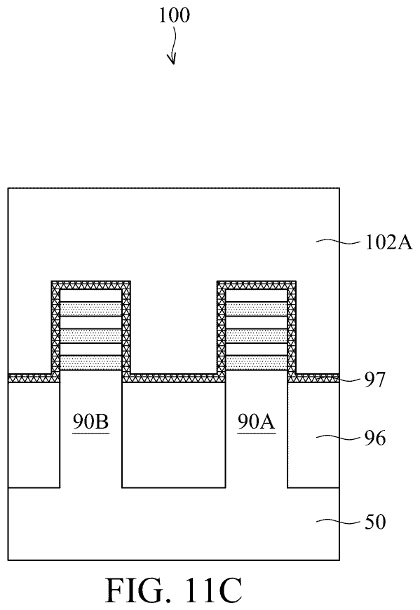

FIGS. 3A, 3B, 4A, 4B, 5A-5C, 6A-6C, 7A-7C, 8A-8C, 9A-9C, 10A-10C, 11A-11C, 12A-12C, 13A, 13B, 14A, 14B, 15A, 15B, 16A, 16B, 17A, 17B, 18A, 18B, 19A-19H, 20A, and 20B are various views (e.g., cross-sectional views, top views) of the NSFET device 100 at subsequent stages of manufacturing, in accordance with an embodiment. FIGS. 3A, 4A, 5A, 6A, 7A, 8A, 9A, 10A, 11B, 12B, 13A, 14A, 15A, 16A, 17A, 18A, 19B, 19C, 19F, and 20A are cross-sectional views along cross-section B-B in FIG. 1. FIGS. 3B, 4B, 5C, 6C, 7C, 8C, 9C, 10C, 11C, 12C, 13B, 14B, 15B, 16B, 17B, 18B, and 19D-19F are cross-sectional views along cross-section A-A in FIG. 1. FIGS. 5B, 6B, 7B, 8B, 9B, and 10B are cross-sectional views along cross-section D-D in FIG. 1. FIGS. 11A, 12A, 19A, 19H, and 20B are top views (e.g., plan views) of the NSFET device 100. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etching process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned portion of the substrate 50 forms the fin 90 (e.g., 90A and 90B), as illustrated in FIGS. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material as the substrate 50.

In the example of FIGS. 3A and 3B, fins 90A and 90B are formed to extend parallel to each other. The fin 90B is formed to be wider than the fin 90A. In other words, a width W2 of the fin 90B is larger than a width W1 of the fin 90A. For example, the width W2 may be about 20% to about 90% larger than the width W1, such as between about 30% and 60% larger than the width W1. The widths W1 and W2 may be achieved by forming masks 94 with different widths over the fins 90A and 90B. As will be discussed hereinafter, p-type source/drain regions are formed over the fin 90A in order to form the p-type NSFETs of a 7T memory cell, and n-type source/drain regions are formed over the fin 90B in order to form the n-type NSFETs of the 7T memory cell. For example, four p-type NSFETs are formed over the fin 90A and three n-type NSFETs are formed over the fin 90B, these seven NSFETs constitute the seven transistors of the 7T memory cell. The wider fin 90B allows a read pass-gate (RPG) transistor (e.g., an n-type NSFET) with strong read stability to be formed over the fin 90B. Details are discussed hereinafter.

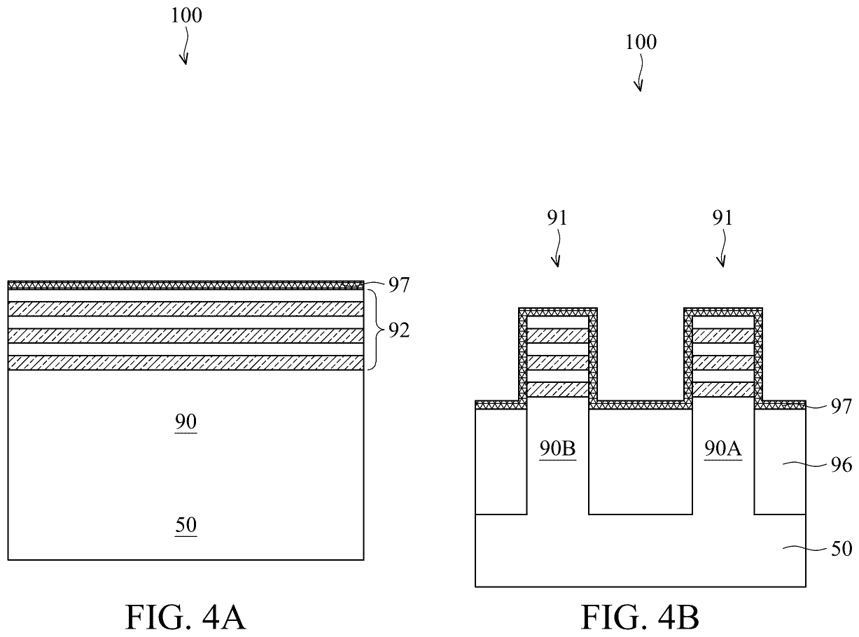

Next, in FIGS. 4A and 4B, Shallow Trench Isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material disposed over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques. In an embodiment, a layer of silicon is conformally formed over the layer stack 92 and over the upper surface of the STI regions 96, and a thermal oxidization process is performed to convert the deposited silicon layer into an oxide layer as the dummy dielectric layer 97.

Next, in FIGS. 5A-5C, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gate 102 and the dummy gate dielectric 97 are collectively referred to as dummy gate structure, in some embodiments.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections D-D and A-A in FIG. 1, respectively. Note that FIG. 5A illustrates the cross-sectional view along the longitudinal direction (e.g., a current flow direction) of one of the fins 90, the cross-sectional views along the longitudinal directions (e.g., current flow directions) of other fins 90 are the same or similar unless otherwise specified. In addition, FIG. 5A illustrates two dummy gates 102 as a non-limiting example, the number of dummy gates 102 over the fins 90 may be any suitable number (see, e.g., FIGS. 11A and 11B).

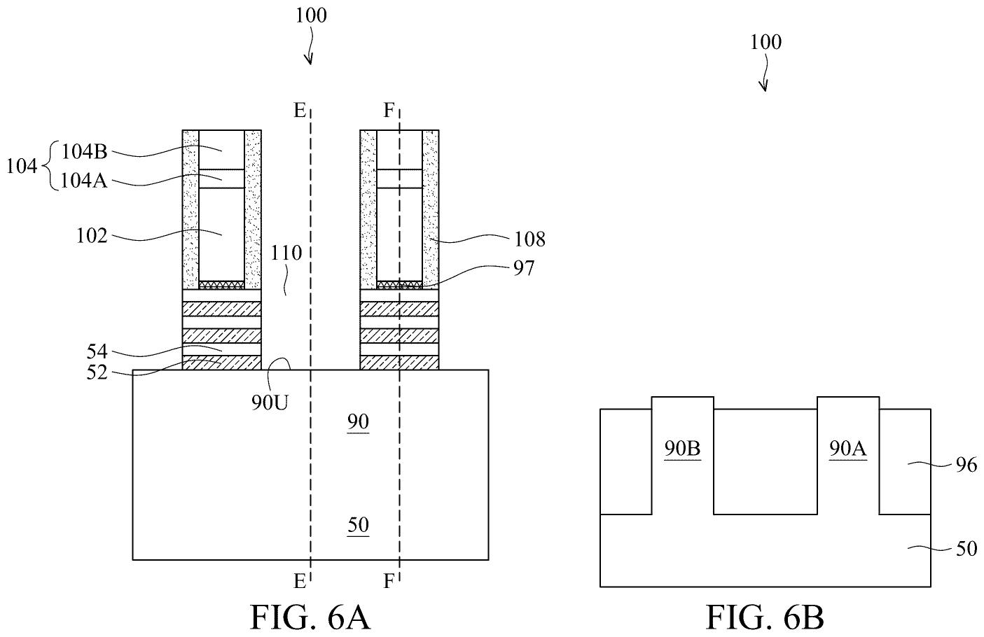

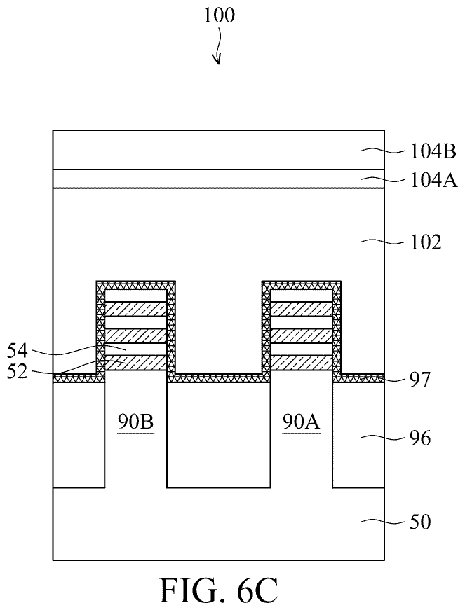

Next, in FIGS. 6A-6C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 (e.g., portions along sidewalls of the dummy gates 102 and the dummy gate dielectric 97) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 10¹⁵ cm⁻³ to about 10¹⁶ cm⁻³. An anneal process may be used to activate the implanted impurities.

Next, openings 110 (which may also be referred to as recesses or source/drain openings) are formed in the layer stacks 92. The openings 110 may extend through the layer stacks 92 and into the fins 90. The openings 110 may be formed by an anisotropic etching process using, e.g., the dummy gates 102 and the gate spacers 108 as an etching mask. Upper surfaces 90U of the fins 90 are exposed at the bottoms of the openings 110. Sidewalls of the openings 110 expose the first semiconductor material 52 and the second semiconductor material 54.

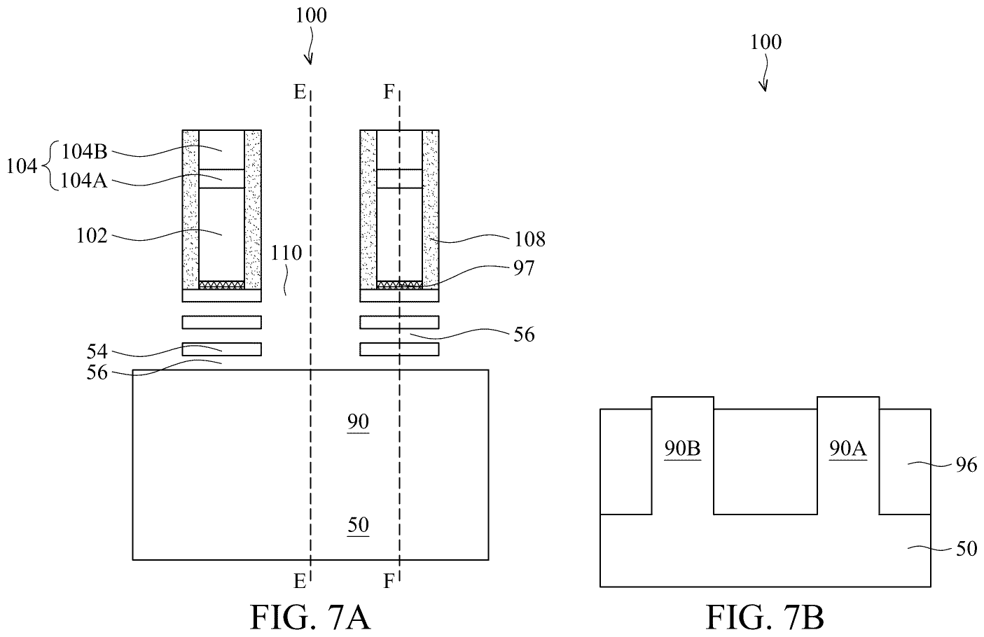

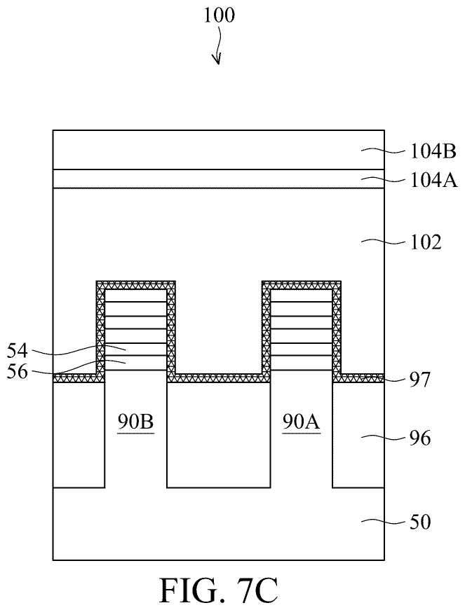

Next, in FIGS. 7A-7C, the first semiconductor material 52 under the dummy gates 102 and exposed by the openings 110 are removed. The first semiconductor material 52 may be removed by performing an isotropic etching process such as wet etching or the like using etchant(s) which is selective to the materials of the first semiconductor material 52, while the second semiconductor material 54, the fins 90, the STI regions 96 remain relatively unetched as compared to the first semiconductor material 52. In embodiments in which the first semiconductor material 52 include, e.g., SiGe, and the second semiconductor material 54 include, e.g., Si or SiC, tetramethylammonium hydroxide (TMAH), ammonium hydroxide (NH4OH), or the like may be used to selectively remove the first semiconductor material 52. After the first semiconductor material 52 is removed, gaps 56 (e.g., empty spaces) are formed between adjacent layers of the second semiconductor material 54, and between the fin 90 and a lowermost layer of the second semiconductor material 54.

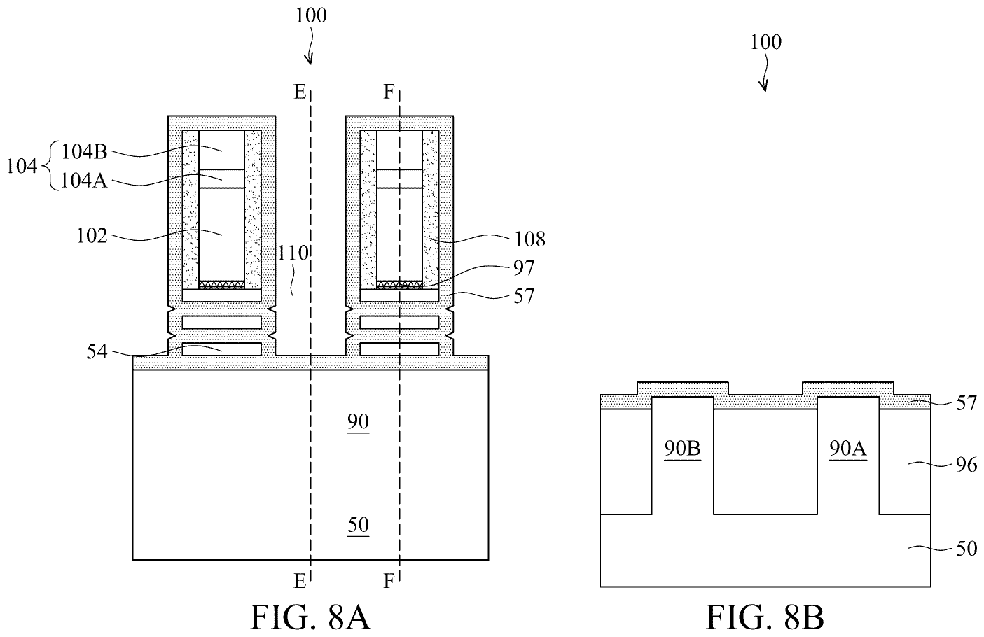

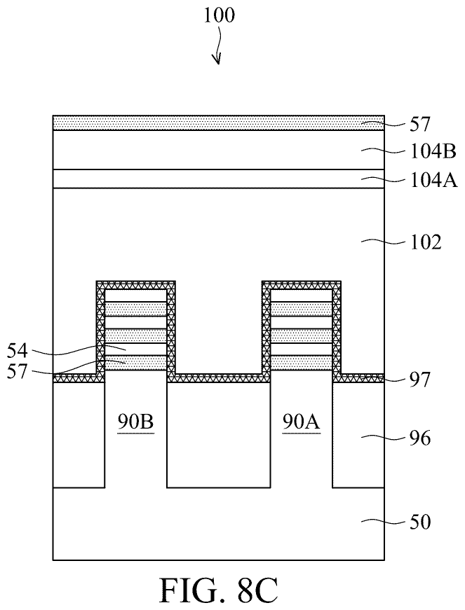

Next, in FIGS. 8A-8C, a disposable material 57 (may also be referred to as a sacrificial material) is deposited in the openings 110 to line the sidewalls and bottoms of the openings 110. The disposable material 57 also fills the gaps 56. The disposable material 57 may be deposited by a conformal deposition process, such as CVD, ALD, or the like. The disposable material 57 may be a dielectric material. In some embodiments, the disposable material 57 includes one or more layers of silicon dioxide (SiO₂), silicon oxynitride (SiON), aluminum oxide (Al₂O₃), or the like. These materials are selected for their properties, such as etching selectivity, which allows for precise removal during the manufacturing process without adversely affecting the adjacent and underlying structures. The choice of the disposable material 57 may depend on the requirements of the semiconductor device being fabricated and the electrical and physical properties of the final product.

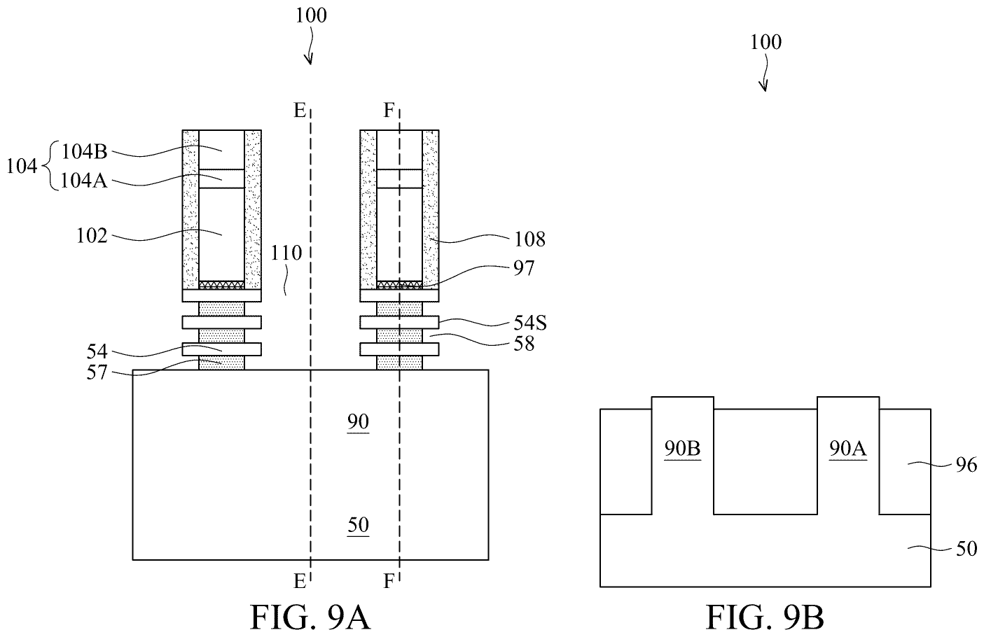

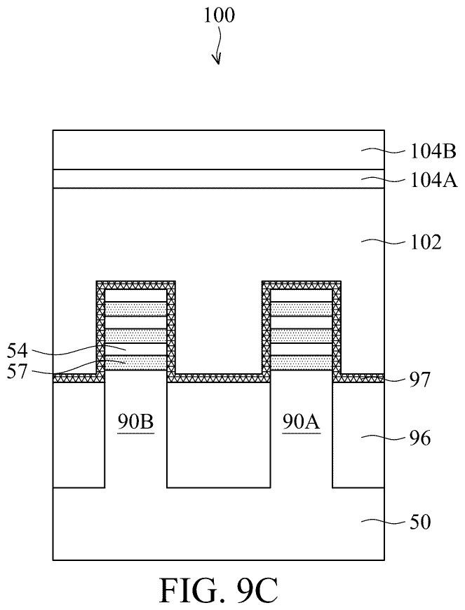

Next, in FIGS. 9A-9C, the disposable material 57 disposed outside the gaps 56 (see FIG. 7A) are removed, and sidewalls of the remaining portions of the disposable material 57 are recessed from respective sidewalls 54S of the second semiconductor material 54 to form sidewall recesses 58.

In some embodiments, an anisotropic etching process, e.g. a dry etching process such as a plasma etching process, is performed to remove the disposable material 57 disposed outside the gaps 56. Next, an isotropic etching process, such as a wet etching process, is performed to recess the remaining portions of the disposable material 57 to form the sidewall recesses 58. The dry etching process and the wet etching process may use etchants selective to the disposable material 57, such that the disposable material 57 is removed without substantially attacking other material(s) and/or structures. In some embodiments, multiple etching cycles, where each etching cycle includes the dry etching process followed by the wet etching process, are performed to remove the disposable material 57 and to form the sidewall recesses 58. The etching cycles are repeated until sidewalls of the disposable material 57 are recessed past sidewalls 54S of the second semiconductor material 54. In some embodiments, the disposable material 57 is etched by a wet etching process using hydrogen fluoride, diluted hydrogen fluoride, another fluorine-based etchant, or the like as an etchant. The wet etching process is performed until sidewalls of the disposable material 57 are recessed past sidewalls 54S of the second semiconductor material 54.

Replacing the first semiconductor material 52 with the disposable material 57 may provide advantages. To appreciate the advantages, consider a reference manufacturing process where the first semiconductor material 52 is not replaced with the disposable material 57. In subsequent source/drain formation steps, one or more high temperature processes may be performed to, for example, activate the dopants in the source/drain regions. When the first semiconductor material 52 (e.g., SiGe) is exposed to high temperatures, germanium in the first semiconductor material 52 may diffuse into and mix with the second semiconductor material 54 (e.g., Si), which is referred to as intermixing between germanium and silicon. Intermixing may increase roughness at interfaces between the first semiconductor material 52 and the second semiconductor material 54, and may cause manufacturing defects that degrade the performance of the resulting transistor devices. By replacing the first semiconductor material 52 with the disposable material 57 prior to the high temperature processes (e.g., source/drain annealing), intermixing is avoided, and manufacturing defects can be reduced and device performance can be improved.

In addition, in subsequent processing of the reference manufacturing process, the first semiconductor material 52 is removed by an etching process to release the second semiconductor material 54 to form nanostructures 54. The intermixing may cause uneven removal of exterior portions of the second semiconductor material 54, such that cross-sections of the nanostructure 54 have a dumbbell shape, with end portions (e.g., portions contacting inner spacers 55) of the nanostructure 54 being taller and/or wider than the middle portion (e.g., portion between the end portions) of the nanostructure 54. Such a dumbbell shape reduces the dimension of the channel regions of the transistor device formed, thus limiting (e.g., reducing) the amount of driving current flowing through the channel regions and limiting the reading or writing capability of the SRMA cell formed. By replacing the first semiconductor material 52 with the disposable material 57, and by choosing the disposable material 57 to have excellent etching selectivity from the second semiconductor material 54, in the subsequent etching process to form the nanostructures 54, the disposable material 57 is selectively removed with little or no etching effect for the second semiconductor material 54. As a result, each of the nanostructures 54 (e.g., the channel region) has a substantially uniform height/width (e.g., having a rectangular cross-section), thus providing better driving current and improved reading/writing capability for the SRAM device formed.

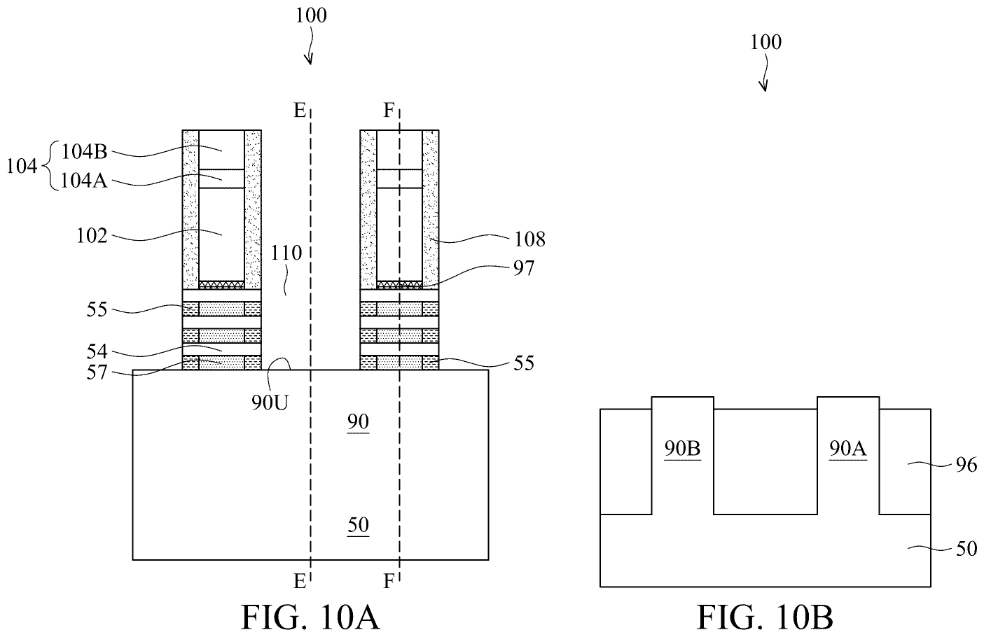

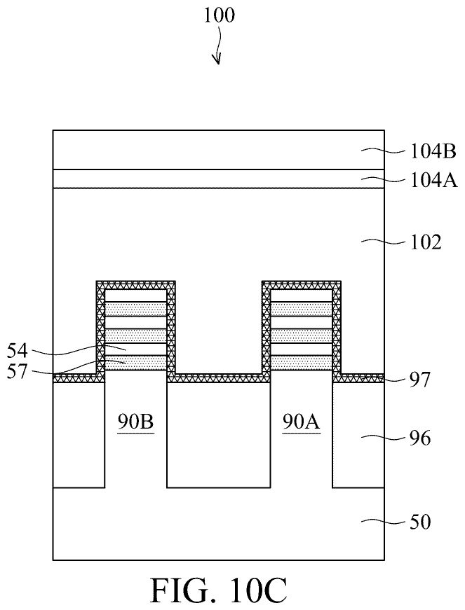

Next, in FIGS. 10A-10C, inner spacers 55 are formed in the sidewall recesses 58. FIGS. 10B and 10C illustrate cross-sectional views of the NSFET device 100 in FIG. 10A along cross-sections E-E and F-F, respectively. In some embodiments, to form the inner spacers 55, an inner spacer layer is formed (e.g., conformally) in the openings 110. The inner spacer layer also fills the sidewall recesses 58 of the sacrificial material 57. The inner spacer layer may be a suitable dielectric material, such as silicon carbonitride (SiCN), silicon oxycarbonitride (SiOCN), or the like, formed by a suitable deposition method such as PVD, CVD, atomic layer deposition (ALD), or the like. Next, an etching process, such as an anisotropic etching process, is performed to remove portions of the inner spacer layers disposed outside the sidewall recesses 58 of the sacrificial material 57. The remaining portions of the inner spacer layers (e.g., portions disposed inside the sidewall recesses 58 of the sacrificial material 57) form inner spacers 55. As illustrated in FIG. 10A, the openings 110 expose sidewalls of the second semiconductor material 54 and expose an upper surface 90U of the fin 90.

FIGS. 11A-11C illustrate the processing following the processing of FIGS. 10A-10C. FIG. 11A is a top view of a portion of the NSFET device 100. FIG. 11B is a cross-sectional view of the NSFET device 100 along cross-section B1-B1 in FIG. 11A, and FIG. 11C is a cross-sectional view of the NSFET device 100 along cross-section A1-A1 in FIG. 11A. Note that for simplicity and to avoid cluttering, not all features of the NSFET device 100 are illustrated in FIG. 11A. For example, FIG. 11A only illustrates the fin 90A and the fin 90B, four dummy gates 102A, 102B, 102C, and 102D (collectively referred to as dummy gates 102) over the fins 90A and 90B, and the gate spacers 108 around the dummy gates 102.

As will be discussed in details hereinafter, seven transistors, which include four p-type transistors and three n-type transistors, are formed in a region 106 of FIG. 11A. These seven transistors are connected by a subsequently formed interconnect structure to form a 7T SRAM memory cell.

As illustrated in FIGS. 11A-11C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In some embodiments, adjacent epitaxial source/drain regions 112 remain separated after the epitaxy process is completed. In other embodiments, these facets cause adjacent epitaxial source/drain regions 112 to merge.

In the illustrated embodiments, n-type devices (e.g., n-type transistors such as n-type NSFETs) are formed over the fin 90B, and p-type devices (e.g., p-type transistors such as p-type NSFETs) are formed over the fin 90A. Therefore, the source/drain regions 112 over the fin 90B are doped with n-type dopant(s), and the source/drain regions 112 over the fin 90A are doped with p-type dopant(s). The fin 90A may be referred to as a p-type fin, and the fin 90B may be referred to as an n-type fin.

Next, a contact etch stop layer (CESL) 116 is formed (e.g., conformally) over the source/drain regions 112 and over the dummy gate 102, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, plasma-enhanced CVD (PECVD), or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used.

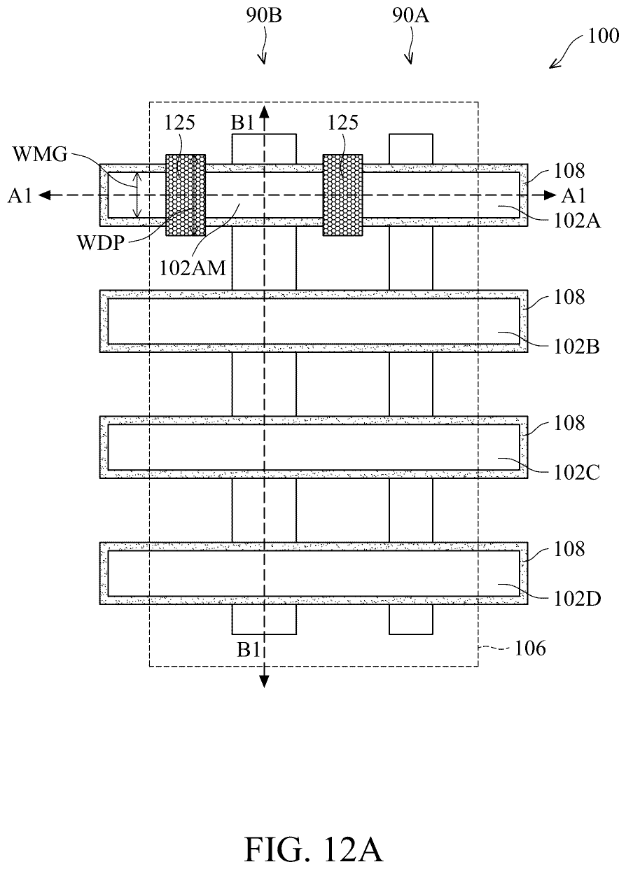

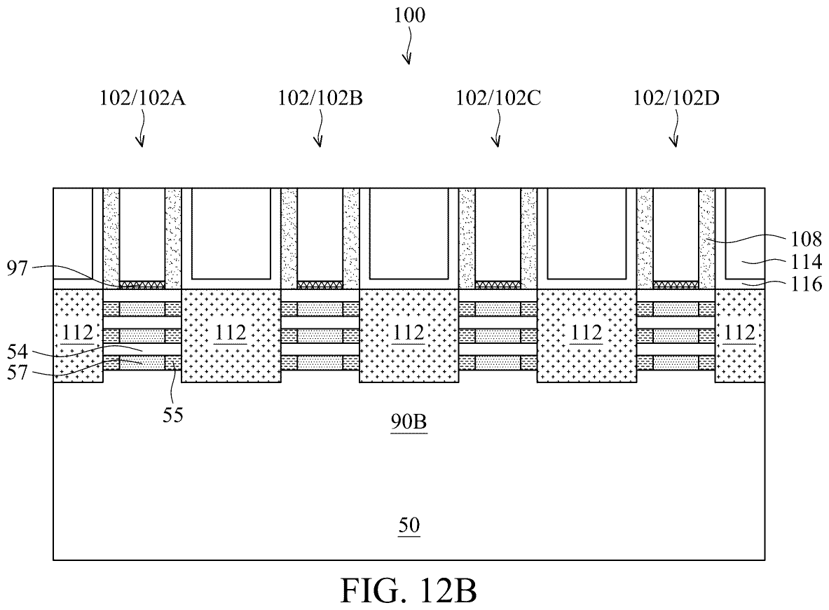

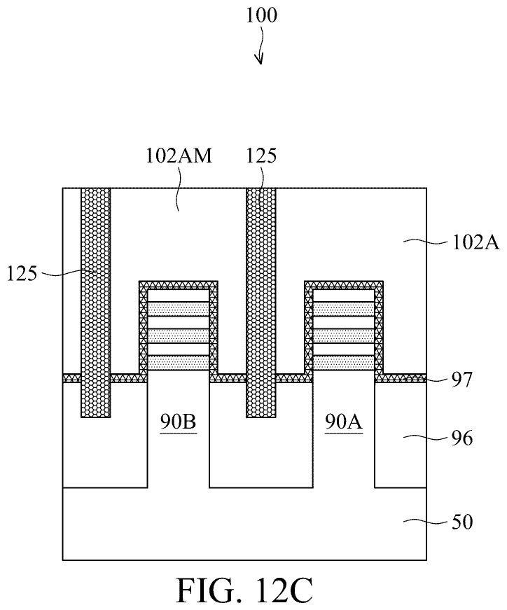

Next, in FIGS. 12A-12C, 13A, 13B, 14A, 14B, 15A, 15B, 16A, and 16B, a Continuous Poly On Diffusion Edge (CPODE) process (also referred to as a Cut Poly On Diffusion Edge (CPODE) process), where a portion of the dummy gate structure (e.g., a portion of dummy gate 102A and dummy gate dielectric 97) is cut (e.g., removed), is performed before the dummy gate structures are replaced by replacement gate structures.

Referring to FIGS. 12A-12C, dielectric plugs 125 are formed to cut the dummy gate 102A and the dummy gate dielectric 97 into a plurality of separate segments. FIG. 12A shows the top view of the NSFET device 100 after the dielectric plugs 125 are formed. FIG. 12B is a cross-sectional view of the NSFET device 100 along cross-section B1-B1 in FIG. 12A, and FIG. 12C is a cross-sectional view of the NSFET device 100 along cross-section A1-A1 in FIG. 12A.

In some embodiments, the dielectric plugs 125 are formed by forming openings that extend through the dummy gate 102A, through the dummy gate dielectric 97, through the first ILD 114, and into the STI region 96 (e.g., using photo lithography and etching techniques), and filling the openings with a dielectric material, such as silicon nitride, silicon oxide, combinations thereof, or the like. Next, a planarization process, such as CMP, may be performed to remove excess portions of the dielectric material from the upper surface of the first ILD 114, and the remaining portions of the dielectric material in the openings form the dielectric plugs 125.

In the illustrated example, the dielectric plugs 125 are formed on opposing sides of the fin 90B. For example, in FIG. 12A, one of the dielectric plugs 125 is formed between the fins 90A and 90B, and another one of the dielectric plugs 125 is formed on an opposing side of the fin 90B. A dimension WDP of the dielectric plug 125, measured along the direction of cross-section B1-B1, is larger than a dimension WMG of the dummy gate 102A to ensure that the dielectric plug 125 cuts the dummy gate 102A into separate segments that are spaced apart from each other, in the illustrated embodiment. In the example of FIG. 12A, a portion 102AM of the dummy gate 102A is disposed between the dielectric plugs 125. As shown in FIG. 12C, the dielectric plugs 125 extend through the dummy gate 102A, through the dummy gate dielectric 97, and into the STI regions 96 to ensure separation of the different segments of the dummy gate structure. Note that the dielectric plugs 125 are not in the cross-section B1-B1 of FIG. 12A, thus are not visible in FIG. 12B.

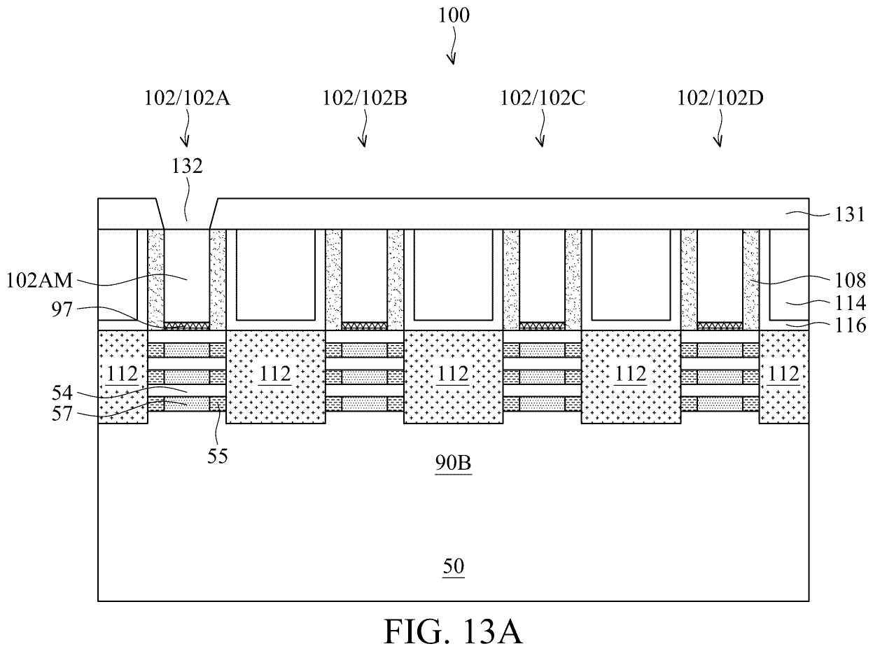

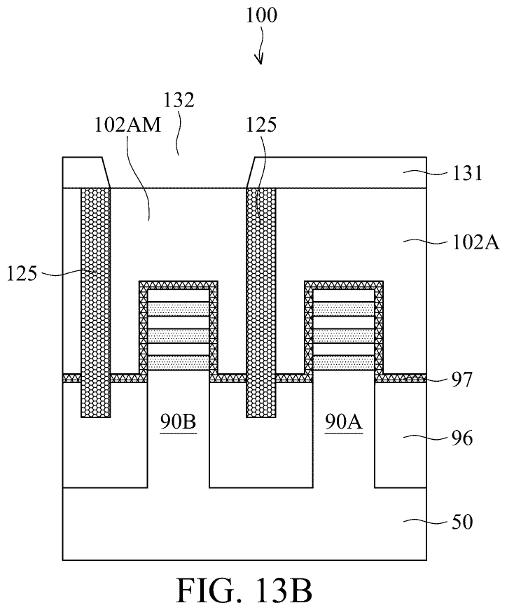

Next, in FIGS. 13A and 13B, a hard mask layer 131 (may also be referred to as a mask layer) is formed over the first ILD 114 and the dummy gates 102. FIGS. 13A and 13B correspond to the cross-sectional views of FIGS. 12B and 12C, respectively. The hard mask layer 131 may be a single-layer hard mask formed of, e.g., silicon nitride, silicon oxynitride, or the like, using a suitable formation method such as CVD. In some embodiments, the hard mask layer 131 has a multi-layered structure. For example, the hard mask layers 131 may include a silicon layer sandwiched between two silicon nitride layers. An opening 132 is formed in the hard mask layer 131 over the portion 102AM of the dummy gate 102A. The opening 132 may be formed using, e.g., photolithography and etching techniques, to expose the portion 102AM of the dummy gate 102A. In some embodiments, in the top view (see, e.g., FIG. 12A), sidewalls of the opening 132 overlap with the boundaries the portion 102AM of the dummy gate 102A.

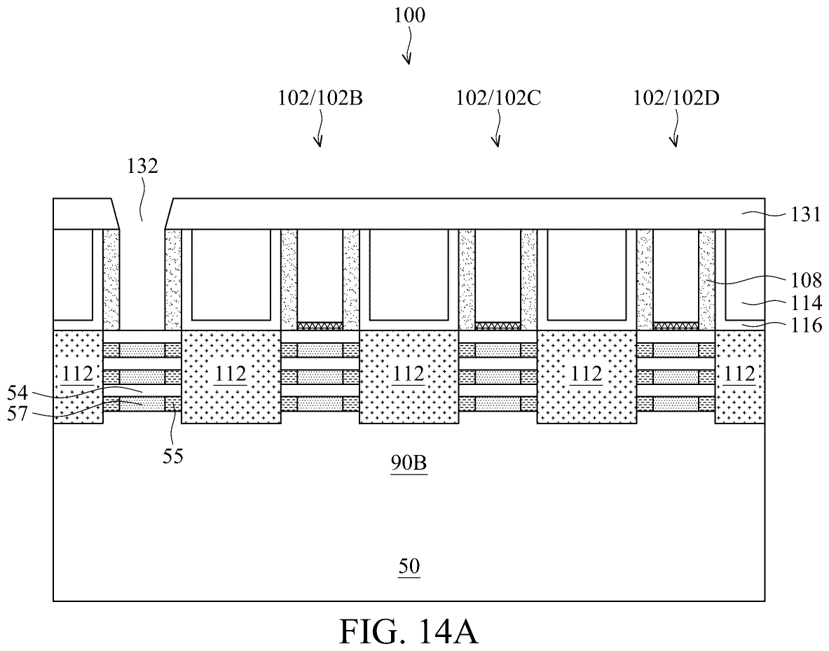

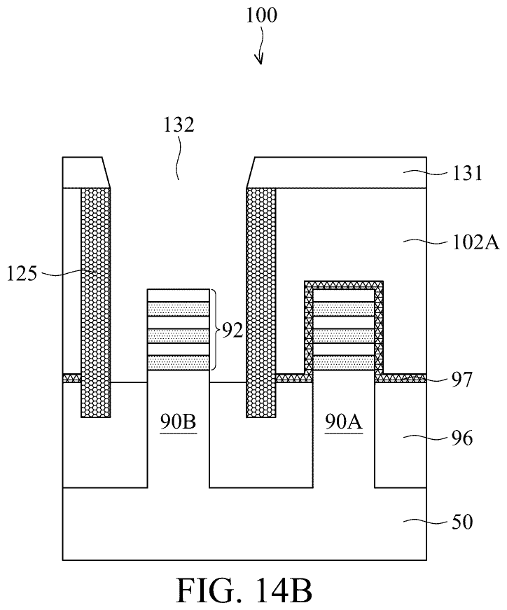

Next, in FIGS. 14A and 14B, the portion 102AM of the dummy gate 102A exposed by (e.g., underlying) the opening 132 is removed, e.g., by an isotropic etching process. In some embodiments, the isotropic etching process is a wet etching process performed using an etching chemical (e.g., an etching fluid). In some embodiments, the isotropic etching process is a dry etching process (e.g., a plasma etching process) performed using an etching gas. The isotropic etching process also removes the dummy gate dielectric 97 underlying the opening 132, as illustrated in FIGS. 14A and 14B. In some embodiments, the isotropic etching process selectively removes the portion 102AM of the dummy gate 102A and the dummy gate dielectric 97 without substantially attacking other materials/structures.

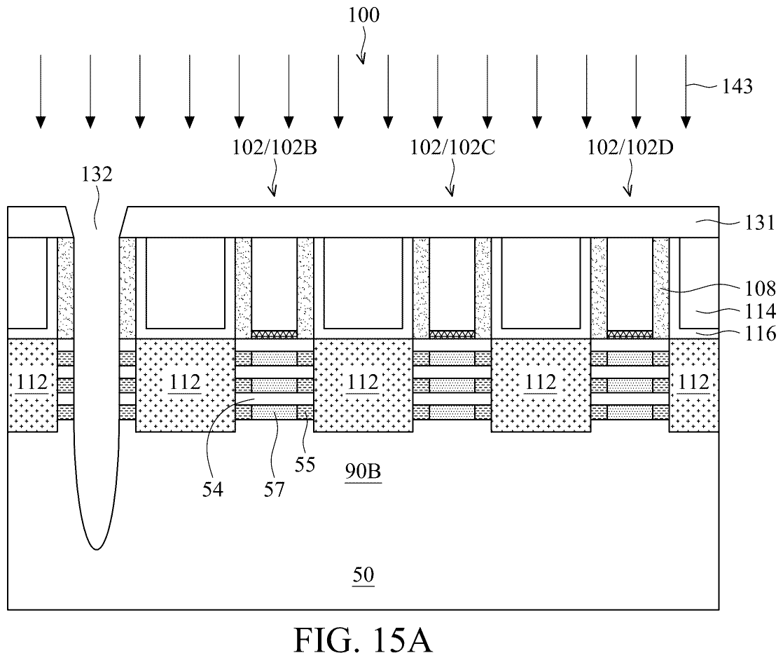

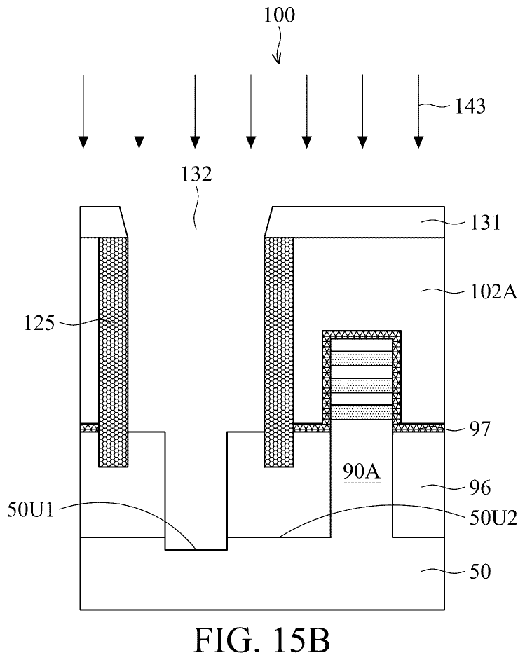

Next, in FIGS. 15A and 15B, an anisotropic etching process 143 (e.g., an isotropic plasma etching process) is performed to remove portions of the disposable material 57 and the second semiconductor material 54 underlying the opening 132. In some embodiments, the anisotropic etching process 143 is a plasma dry etching process. In some embodiments, the isotropic etching process illustrated in FIGS. 14A and 14B is omitted, and an anisotropic etching process same as or similar to the anisotropic etching process 143 is performed to remove portions of the disposable material 57 and the second semiconductor material 54 underlying the opening 132.

As illustrated in FIGS. 15A and 15B, the portion 102AM of the dummy gate 102A exposed by the opening 132 is removed. Portions of the disposable material 57 and the second semiconductor material 54 underlying the opening 132 are also removed. Portions of the disposable material 57 and the second semiconductor material 54 under (e.g., directly under) the gate spacers 108 may remain, as illustrated in FIG. 15A. In addition, the fin 90B under the openings 132 is also removed. Therefore, as shown in FIG. 15B, the opening 132 extends through the STI region 96 and into the substrate 50. As a result, an upper surface 50U1 of the portions of the substrate 50 underlying the opening 132 is lower (e.g., more recessed) than an upper surface 50U2 of other (un-etched) portions of the substrate 50. In the illustrated embodiment, the anisotropic etching process 143 is selective to (e.g., having a much higher etching rate for) the materials of the disposable material 57 and the second semiconductor material 54, and has little or no etching effect on the STI region 96.

As illustrated in FIGS. 15A and 15B, the opening 132 (may also be referred to as a recess) exposes sidewalls of the dielectric plugs 125 facing the nanostructures 54, and exposes inner sidewalls of the gate spacers 108 facing the opening 132.

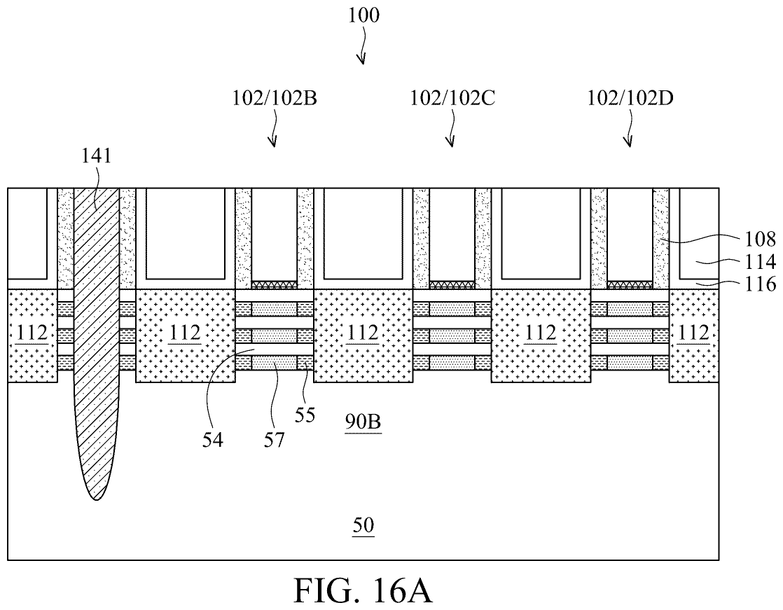

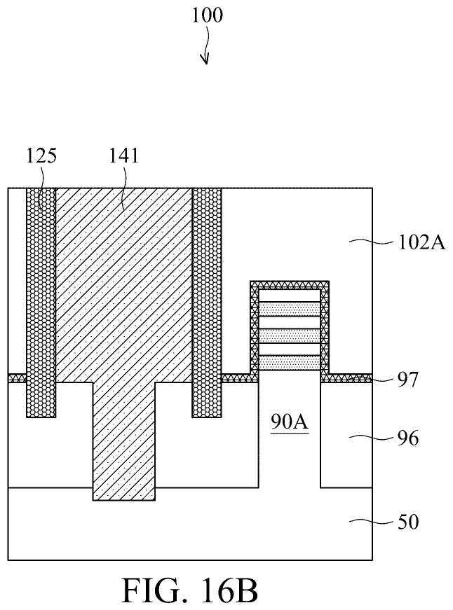

Next, in FIGS. 16A and 16B, a dielectric material 141 is formed in the opening 132 and over the hard mask layer 131. The dielectric material 141 may be, e.g., silicon oxide, silicon nitride, silicon oxynitride, silicon oxycarbonitride, combinations thereof, or multilayers thereof. A suitable formation method, such as CVD, PECVD, ALD, or the like, may be used to form the dielectric material 141. In some embodiments, the dielectric material 141 includes multiple layers of different dielectric materials. In some embodiments, the dielectric material 141 includes multiple layers of the same dielectric material (e.g., SiO or SiN) formed by different formation methods. For example, a layer of the dielectric material may be formed by ALD, then another layer of the same dielectric material may be formed by, e.g., CVD, to fill the opening 132. The dielectric material formed by ALD may be dense and have improved etching resistance, while the dielectric material formed by CVD can be formed quickly to reduce production time and cost.

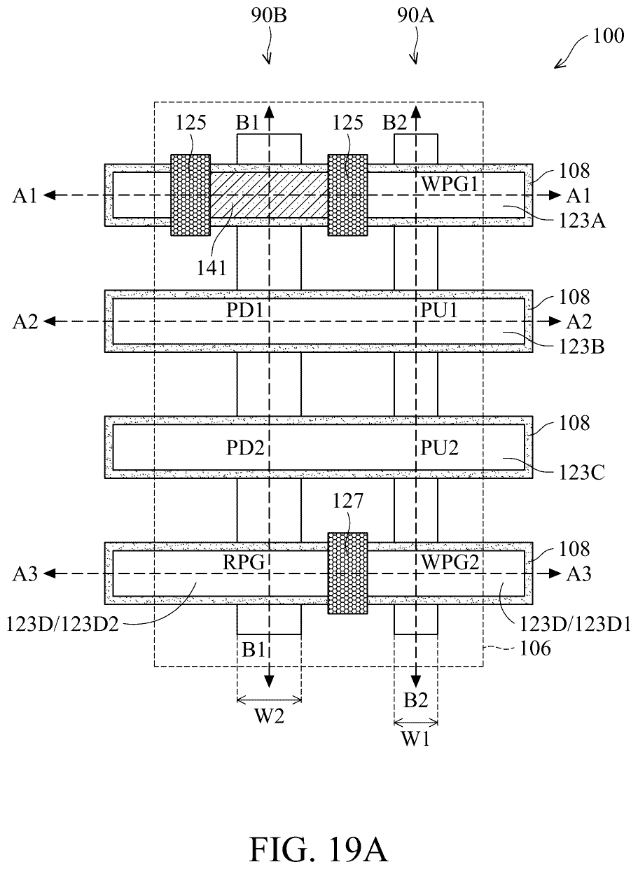

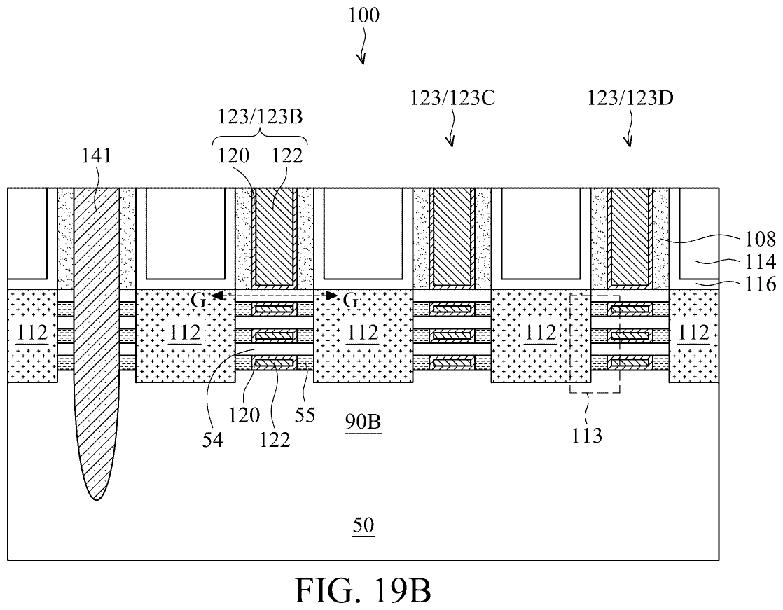

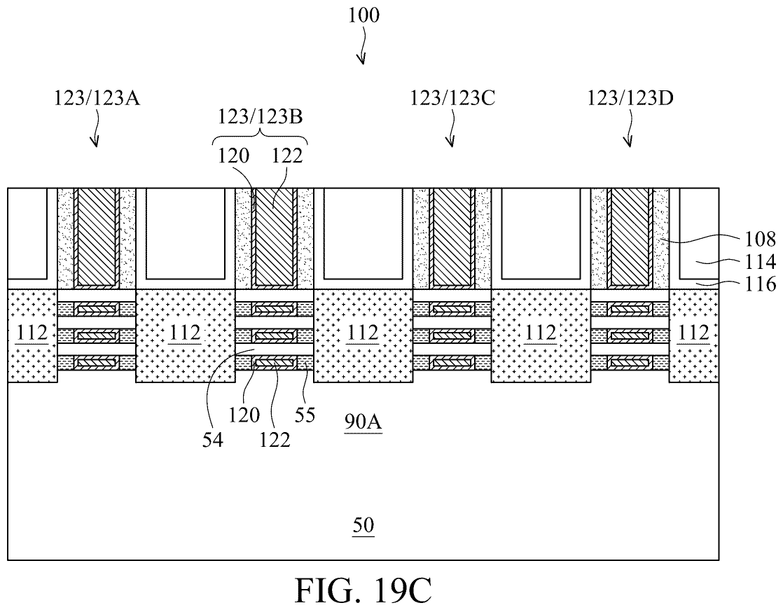

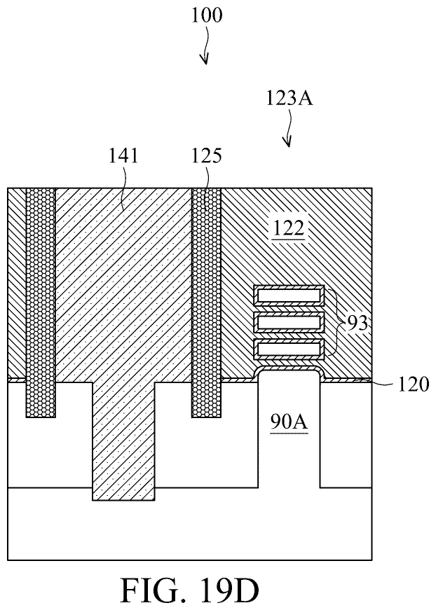

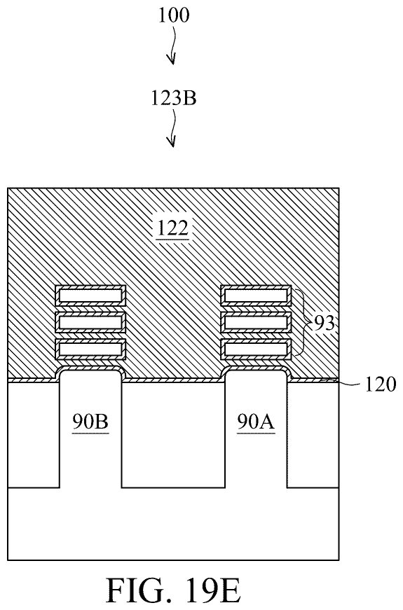

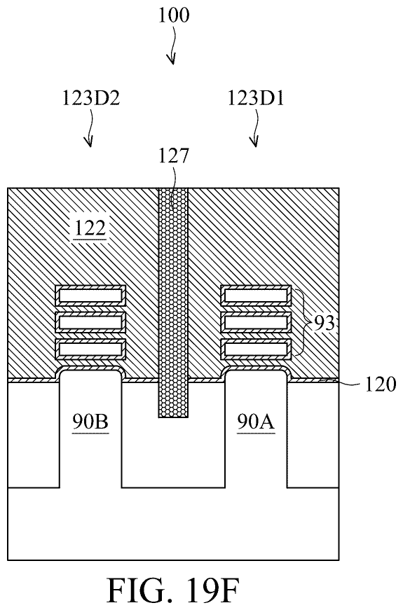

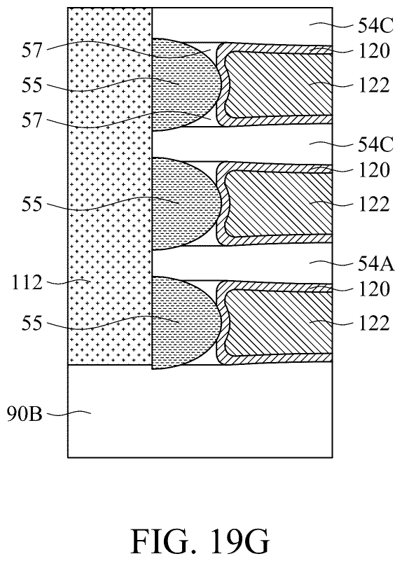

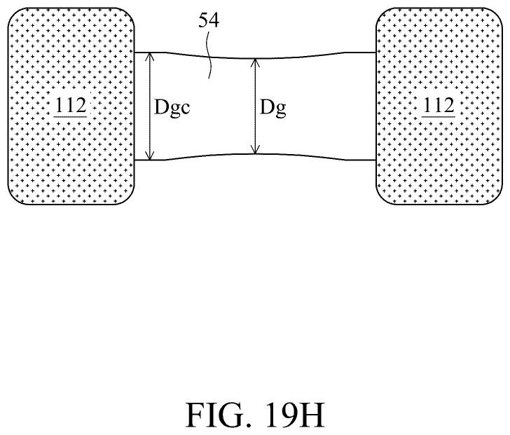

Next, a planarization process, such as CMP, is performed to remove the dielectric material 141 and the hard mask layer 131 from the upper surface of the first ILD 114. The remaining portions of the dielectric material 141 in the opening 132 form a dielectric structure 141 (may also be referred to as an isolation structure). FIG. 19A shows the top view of the dielectric structure 141. As illustrated in FIG. 19A, the dielectric structure 141 is disposed between the dielectric plugs 125 along the direction of cross-section A1-A1, and is disposed between the gate spacers 108 of the subsequently formed gate structure 123A along the direction of cross-section B1-B1.

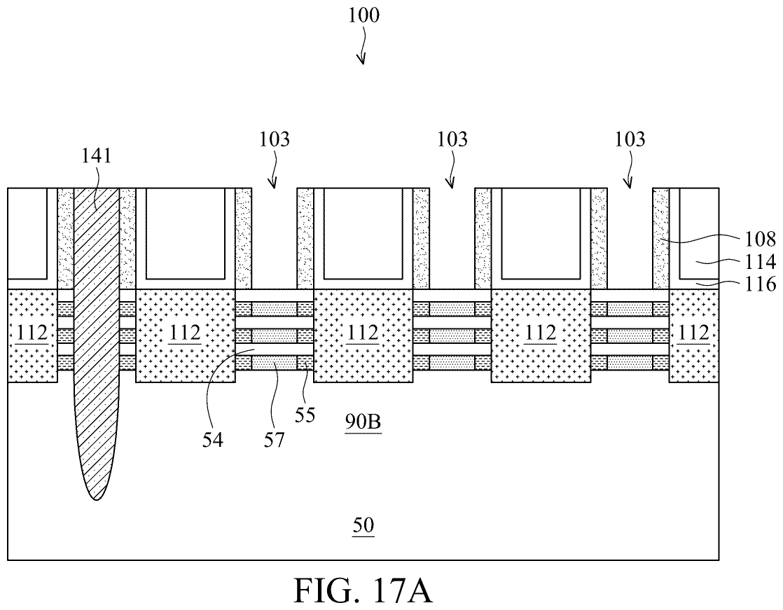

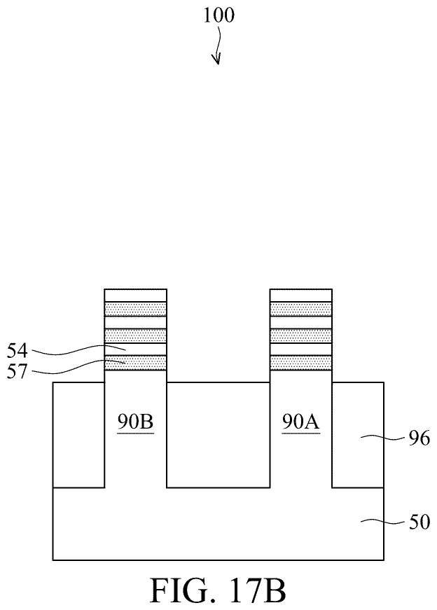

FIGS. 17A, 17B, 18A, 18B, and 19A-19F illustrate a replacement gate process where the dummy gate structures (e.g., 102 and 97) are removed and replaced by replacement gate structures 123 (e.g., metal gate structures).

Next, in FIGS. 17A and 17B, the dummy gates 102 are removed in an etching step(s), so that recesses 103 are formed between respective gate spacers 108. In some embodiments, the dummy gates 102 are removed by an anisotropic dry etching process. For example, the etching process may include a dry etching process using reaction gas(es) that selectively etch the dummy gates 102 without etching the first ILD 114 and the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102.

In some embodiments, the dummy gate dielectric 97 in the recesses 103 is removed. An etching process, such as an isotropic etching process, may be performed to remove the dummy gate dielectric 97. In an embodiment, an isotropic etching process using an etching gas that comprises HF and NH₃ is performed to remove the dummy gate dielectric 97. As illustrated in FIGS. 17A and 17B, each recess 103 exposes underlying channel regions of the NSFET. Each channel region is disposed between neighboring pairs of the epitaxial source/drain regions 112.

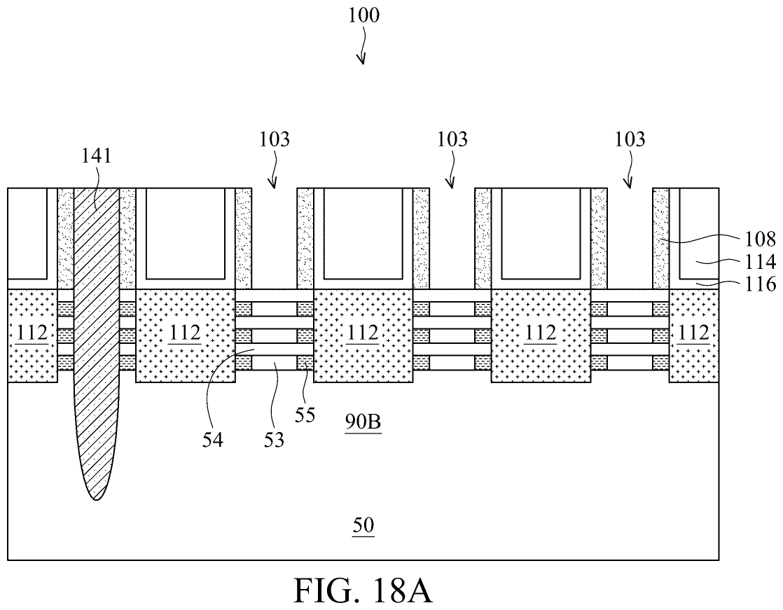

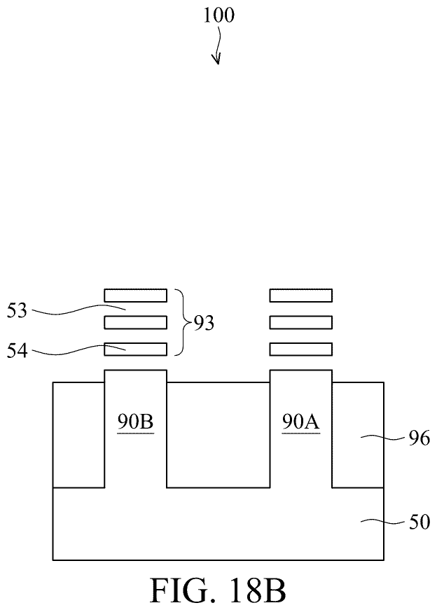

Next, in FIGS. 18A and 18B, the disposable material 57 (e.g., portions exposed by the recesses 103) is removed to release the second semiconductor material 54. After the disposable material 57 is removed, the second semiconductor material 54 (e.g., portions underlying the dummy gates 102 before the dummy gates 102 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100 formed. As illustrated in FIGS. 18A and 18B, gaps 53 (e.g., empty spaces) are formed between the nanostructures 54 and between the lowermost nanostructure 54 and the fins 90 by the removal of the disposable material 57. In some embodiments, the nanostructures 54 are nanosheets or nanowires, depending on, e.g., the dimensions (e.g., size and/or aspect ratio) of the nanostructures 54.

In some embodiments, the disposable material 57 is removed by a selective etching process using an etchant that is selective to (e.g., having a higher etch rate for) the disposable material 57, such that the disposable material 57 is removed without substantially attacking the second semiconductor material 54. In some embodiments, an isotropic etching process, such as a wet etching process or the like, is performed to remove the disposable material 57. In embodiments where the disposable material 57 include, e.g., SiO₂, and the second semiconductor material 54 include, e.g., Si or SiC, hydrogen fluoride, diluted hydrogen fluoride, another fluorine-based etchant, or the like, may be used to remove the disposable material 57.

In some embodiments, a high etching selectivity of 10000 or more is achieved between the second semiconductor material 54 and the disposable material 57. In other words, the disposable material 57 is removed by the isotropic etching process at an etching rate 10000 times or more than the etching rate of the second semiconductor material 54. As a result, the cross-section of the nanostructures 54 has a rectangular shape (e.g., uniform width/height), thus avoiding the performance issues (e.g., lower driving current, higher channel resistance) related with dumbbell shaped nanostructures.

As illustrated in FIG. 18A, each of the nanostructures 54 has a rectangular shaped cross-section along the longitudinal axis of the fin. Similarly, in FIG. 18B, in a cross-section along a direction perpendicular to the longitudinal axis of the fin and across a middle portion of the nanostructure 54, each of the nanostructures 54 has a rectangular shaped cross-section.

Next, in FIGS. 19A-19F, gate dielectric layers 120 and gate electrodes 122 are formed to form replacement gate structures 123 (e.g., 123A, 123B, 123C, and 123D). FIG. 19A illustrates the top view of the NSFET device 100. FIGS. 19B and 19C illustrate the cross-sectional views along cross-sections B1-B1 and B2-B2 in FIG. 19A, respectively. FIGS. 19D, 19E, and 19F illustrate the cross-sectional views along cross-sections A1-A1, A2-A2, and A3-A3 in FIG. 19A, respectively.

The gate dielectric layers 120 are deposited conformally in the recesses 103, such as on the top surfaces and the sidewalls of the semiconductor fin 90, and on sidewalls of the gate spacers 108. The gate dielectric layers 120 may also be formed on the top surface of the first ILD 114. Notably, the gate dielectric layers 120 are formed to wrap around the nanostructures 54. In accordance with some embodiments, the gate dielectric layers 120 comprise silicon oxide, silicon nitride, or multilayers thereof. In some embodiments, the gate dielectric layers 120 are formed of a high-k dielectric material, and in these embodiments, the gate dielectric layers 120 may have a k value greater than about 7.0, and may include a metal oxide or a silicate of Hf, Al, Zr, La, Mg, Ba, Ti, or Pb, or combinations thereof. The formation methods of the gate dielectric layers 120 may include Molecular-Beam Deposition (MBD), ALD, PECVD, and the like.

Next, a gate electrode material 120 is deposited over and around the gate dielectric layers 120, and fill the remaining portions of the recesses 103. The gate electrode material may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill metal material. After the filling of the gate electrode material 122, a planarization process, such as a CMP, may be performed to remove the excess portions of the gate dielectric layers 120 and the gate electrode material 122, which excess portions are over the top surface of the first ILD 114. The remaining portions of the gate electrode material 122 and the gate dielectric layers 120 thus form the gate electrodes 122 and the gate dielectric layer 120, respectively, of the replacement gate structures 123 of the resulting NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

Still referring to FIGS. 19A-19F, a dielectric plug 127 (may also be referred to as a dielectric structure) is formed between the fins 90A and 90B to cut the gate structure 123D into two separate segments, and the two separate segments over the fin 90A and 90B form gate structures 123D1 and 123D2, respectively (see FIGS. 19A and 19F). In some embodiments, the dielectric plug 127 is formed by forming an opening in the gate structure 123D and the first ILD 114 (e.g., using photo lithography and etching techniques), and filling the opening with a dielectric material, such as silicon nitride, silicon oxide, combinations thereof, or the like. Next, a planarization process, such as CMP, may be performed to remove excess portions of the dielectric material from the upper surface of the first ILD 114, and the remaining portions of the dielectric material in the opening form the dielectric plugs 127. As shown in FIG. 19F, the dielectric plug 127 extends through the gate structure 123D and into the STI regions 96 to ensure separation of the different segments of the gate structure 123D. Note that the dielectric plug 127 is not in the cross-sections A1-A1 and A2-A2 of FIG. 13C, thus is not visible in FIGS. 19D and 19E. The dielectric structure 141 is shown in FIG. 19D.

As illustrated in the top view of FIG. 19A, an NSFET (labeled as WPG1 in FIG. 19A) is formed at a location where the gate structure 123A intersects the fin 90A. For example, a portion of the gate structure 123A over (e.g., directly over) the fin 90A, the underlying nanostructures 54, and the source/drain regions 112 (not shown in FIG. 19A but shown in FIG. 19C) over the fin 90A and on opposing sides of the portion of the gate structure 123A form the NSFET WPG1. Recall that the source/drain regions 112 over the fin 90A are p-type source/drains, and therefore, the NSFET WPG1 is a p-type NSFET. Note that the dielectric structure 141 embedded in the gate structure 123A is disposed over (e.g., directly over) the fin 90B, and as a result, no NSFET is formed at the location where dielectric structure 141 insects the fin 90B.

Still referring to FIG. 19A, the gate structure 123B intersects the fins 90A and 90B. A first portion of the gate structure 123B over the fin 90A forms a p-type NSFET (labeled as PU1 in FIG. 19A) with the underlying nanostructures 54 and the p-type source/drain regions 112 (see FIG. 19C) over the fin 90A and on opposing sides of the first portion of the gate structure 123B. Similarly, a second portion of the gate structure 123B over the fin 90B forms an n-type NSFET (labeled as PD1 in FIG. 19A) with the underlying nanostructures 54 and the n-type source/drain regions 112 (see FIG. 19B) over the fin 90B and on opposing sides of the second portion of the gate structure 123B. The gate terminal of the p-type NSFET PU1 is therefore connected to the gate terminal of the n-type NSFET PD1.

Similarly, the gate structure 123C intersects the fins 90A and 90B. A first portion of the gate structure 123C over the fin 90A forms a p-type NSFET (labeled as PU2 in FIG. 19A) with the underlying nanostructures 54 and the p-type source/drain regions 112 (see FIG. 19C) over the fin 90A and on opposing sides of the first portion of the gate structure 123C. A second portion of the gate structure 123C over the fin 90B forms an n-type NSFET (labeled as PD2 in FIG. 19A) with the underlying nanostructures 54 and the n-type source/drain regions 112 (see FIG. 19B) over the fin 90B and on opposing sides of the second portion of the gate structure 123C. The gate terminal of the p-type NSFET PU2 is therefore connected to the gate terminal of the n-type NSFET PD2.

The gate structure 123D is cut (e.g., separated) by the dielectric plug 127 into two separate gate structures 123D1 and 123D2 over the fins 90A and 90B, respectively. The gate structure 123D1 forms a p-type NSFET (labeled as WPG2 in FIG. 19A) with the underlying nanostructures 54 and the p-type source/drain regions 112 (see FIG. 19C) over the fin 90A and on opposing sides of the gate structure 123D1. The gate structure 123D2 over the fin 90B forms an n-type NSFET (labeled as RPG in FIG. 19A) with the underlying nanostructures 54 and the n-type source/drain regions 112 (see FIG. 19B) over the fin 90B and on opposing sides of the gate structure 123 D2.

As discussed above, a total of seven NSFETs, which includes four p-type NSFETs (e.g., WPG1, PU1, PU2, and WPG2) and three n-type NSFETS (e.g., PD1, PD2, and RGP), are formed in the region 106 of FIG. 19A. These seven NFSETs are further interconnected by a subsequently formed interconnect structure 155 to form a 7T SRAM memory cell. Details are discussed hereinafter.

FIG. 19G illustrates a zoomed-in view of an area 113 in FIG. 19B, in an embodiment. In the example of FIG. 19G, the inner spacers 55 have convex inner sidewalls facing the gate electrode 122. In some embodiments, after the disposable material 57 is removed and replaced by the gate structures (e.g., 120 and 122), some residual portions of the disposable material 57 remain between the inner spacers 55 and the gate structures. These remaining portions of the disposable material 57 do not adversely affect the device performance. In contrast, if the reference manufacturing process discussed above is used, there would be remaining portions of the second semiconductor material (e.g., SiGe) at the locations of the remaining portions of the disposable material 57 illustrated in FIG. 19G. The remaining portions of the second semiconductor material (e.g., SiGe) may adversely affect the performance of the device formed (e.g., by causing leakage current).

FIG. 19H illustrates a cross-sectional view of a portion of the NFFET device 100 along cross-section G-G in FIG. 19B. FIG. 19H therefore illustrates a top view of one of the nanostructures 54 and the source/drain regions 112 on opposing sides of the nanostructure 54. For simplicity, not all features of the NSFET device 100 are illustrated in FIG. 19H. In FIG. 19H, the width of the nanostructure 54 proximate to the source/drain regions 112 is denoted as Dgc, and the width the nanostructure 54 at a midpoint between the source/drain regions 112 is denoted as Dg. Note that the difference between the width Dgc and the width Dg is exaggerated in FIG. 19H. The ratio between the width Dgc and the width Dg is between about 1 and about 1.05 (e.g., 1<Dgc/Dg<1.05), in some embodiments. In other words, the nanostructure 54 has a substantially rectangular shaped cross-section, thus maintaining the dimension of the nanostructure 54 with little or no loss of width in the middle portion of the nanostructure 54. The DOI process, by replacing the first semiconductor material 52 (e.g., SiGe) with the disposable material 57 (e.g., an oxide), provides excellent etching selectivity (e.g., larger than 10000) between the second semiconductor material 54 (e.g. Si) and the disposable material 57, thus is able to maintain the dimension of the nanostructure 54. In contrast, for nanostructures 54 formed without the DOI process, the ratio between the width Dgc and the width Dg is larger than, e.g., 1.1 (e.g., Dgc/Dg>1.1) and may have a dumbbell shaped cross-section. Improved driving current is achieved by the nanostructure 54 formed using the DOI process. For example, for p-type NSFETs, an improvement in driving current of about 20% is achieved, and for n-type NSFETs, an improvement in driving current of about 5% is achieved.

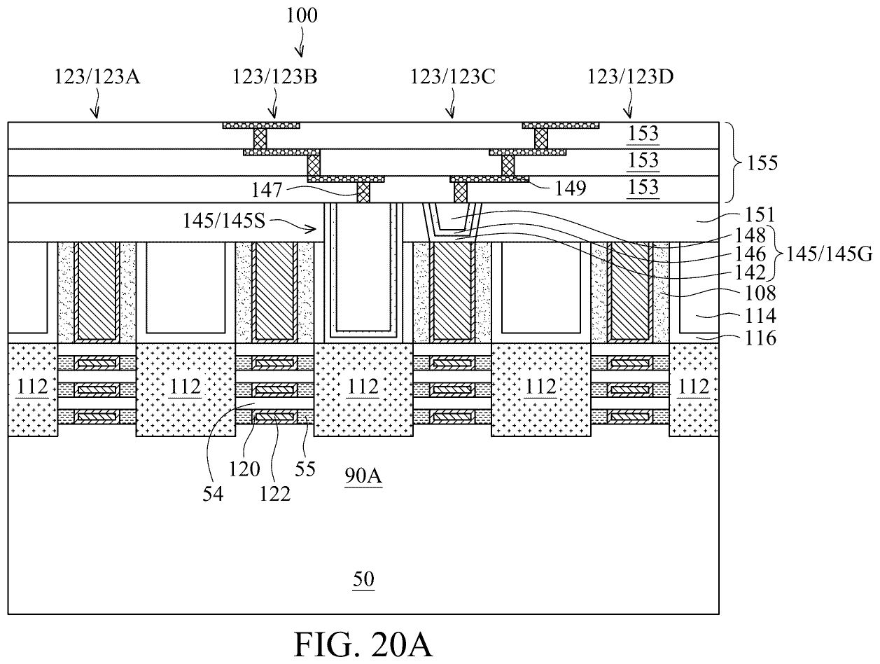

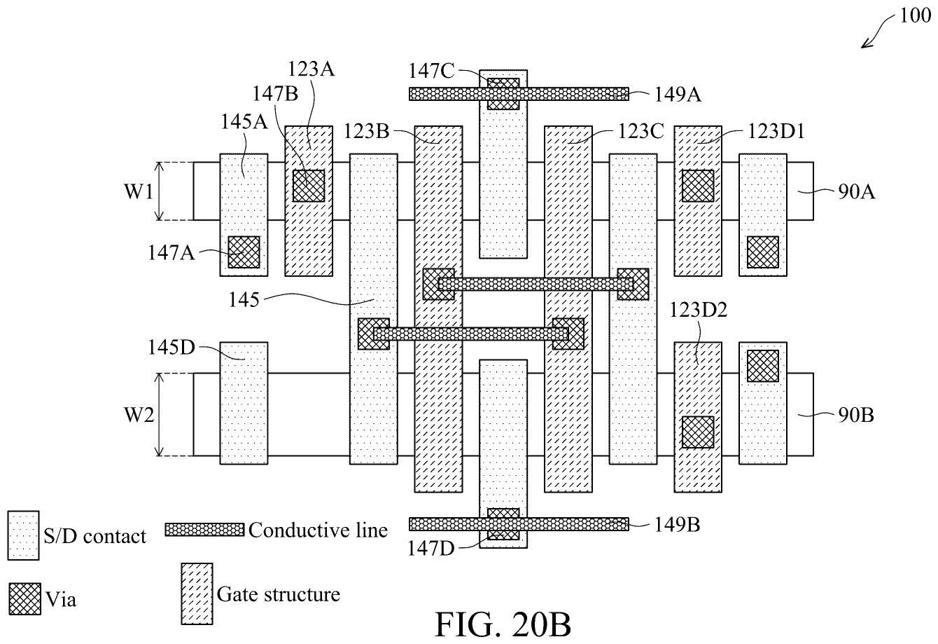

Next, in FIG. 20A, a second ILD 151 is formed over the first ILD 114. Source/drain contacts 145S are formed to extend through the first ILD 114 and the second ILD 151 to electrically coupled to respective source/drain regions 112. Gate contacts 145G are formed to extend through the second ILD 151 to electrically coupled to respective gate structures 123. The source/drain contacts 145S and the gate contacts 145G are collectively referred to as contacts 145. In addition, an interconnect structure 155, which includes dielectric layers 153 and conducive features (e.g., conductive lines 149 and vias 147) formed in the dielectric layers 153, is formed over the second ILD 151 to interconnect the electrical components formed in/over the substrate 50 to form functional circuits (e.g., 7T memory cell).

The second ILD 151 may be formed of a same dielectric material as the first ILD 114 using a same formation method. The contacts 145 may include a barrier layer 142 (e.g., TiN, TaN or the like), a seed layer 146 (e.g., Cu), and a fill metal 148 (e.g., Cu, W, Co, or the like). In some embodiments, the source/drain contact 145S is formed by: forming a patterned mask layer over the second ILD 151, where an opening of the patterned mask layer overlies a respective source/drain region 112; removing a portion of the second ILD 151 and a portion of the first ILD 114 that underlie the opening; conformally forming the barrier layer 142 and the seed layer 146 in the openings; and filling the opening with the fill metal 148. The patterned mask layer is then removed, e.g., by a CMP process. Note that in the example of FIG. 20A, the portion of the first ILD 114 disposed between respective sidewalls of the CESL 116 is completely removed, such that the barrier layer 142 of the source/drain contact 145S contacts (e.g., physically contacts) the sidewalls of the CESL 116. The illustrated source/drain contact 145S achieves increased volume and reduced electrical resistance, which improves the electrical performance of the device formed. The gate contacts 145G may be formed of a same or similar method as the source/drain contacts 145S, thus details are not repeated. The dielectric layers 153 of the interconnect structure 155 may be formed of a suitable dielectric material, such as silicon oxide or a low-k dielectric material. The conductive lines 149 and the vias 147 of the interconnect structure 155 may be formed of a suitable electrically conductive material(s) (e.g., Cu) using any suitable formation method.

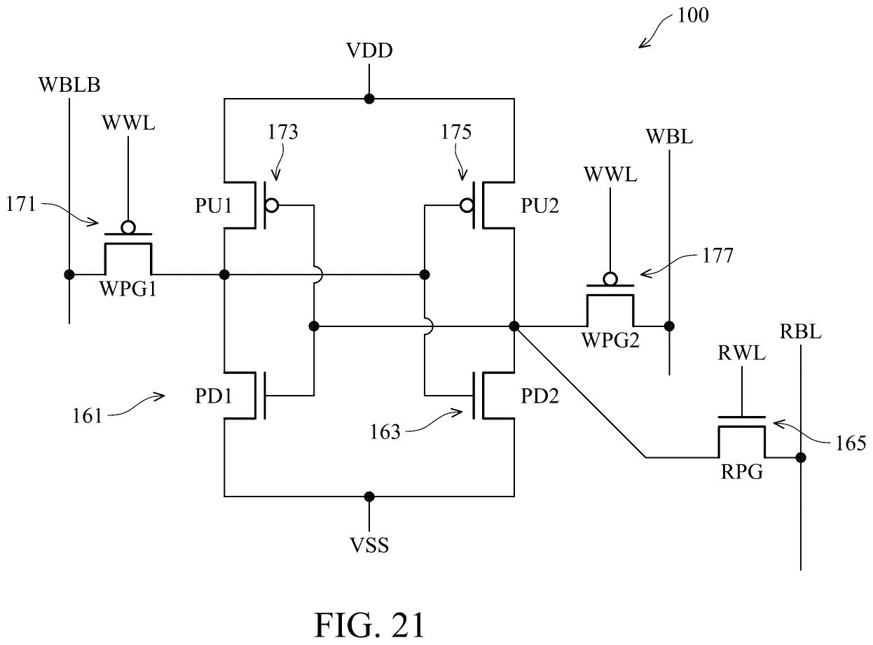

The interconnect structure 155 and the contacts 145 connect the seven transistors formed in the region 106 of FIG. 19A to form a 7T memory cell. Note that FIG. 20A is used to illustrate the structure of contacts 145 and the interconnect structure 155, but not the specific electrical connections between the different NSFETs. FIG. 20B shows details of the electrical connections between the seven NSFETs in a 7T memory cell. FIG. 21 is the equivalent circuit diagram of the 7T memory cell of FIG. 20B.

FIG. 20B illustrates a top view of the NSFET device 100 showing the electrical connections of the seven NSFETs in a 7T memory cell. FIG. 20B may also be referred to as a layout view of the NSFET device 100. The seven NSFETs in FIG. 20B correspond to the seven NSFETs in the region 106 of FIG. 19A. For simplicity, not all features of the NSFET device 100 are illustrated in FIG. 20B. FIG. 20B shows the fins 90A and 90B, the gate structures 123A, 123B, 123C, 123D 1, and 123D2, and source/drain contacts 145 (e.g., 145A, 145D). In addition, FIG. 20B illustrates vias 147 (e.g., 147A, 147B, 147C, 147D) and conductive lines 149 (e.g., 149A, 149B) of the interconnect structure 155. The width W1 of the fin 90A is smaller than the width W2 of the fin 90B, as discussed above.

In the top view of FIG. 20B, a feature at the foreground partially blocks a feature behind it, and the feature at the foreground is disposed at a higher vertical level (e.g., larger distance from substrate 50) than the feature behind it. If multiple features overlap each other, the relative vertical level of each feature can be determined by how the features block each other. For example, in FIG. 20B, the conductive lines 149 are at the highest vertical level, the vias 147 are below the conductive lines 149, and the source/drain contacts 145 are below the vias 147. The gate structures 123 are also below the vias 147 and are connected to the vias 147 by gate contacts (e.g., 145G in FIG. 20A). For simplicity, gate contacts 145G are not illustrated in FIG. 20B. The fins 90 are below the gate structures 123.

In FIG. 20B, an overlap (e.g., intersection) between a feature and a feature immediately below it indicates an electrical connection between the two features. For example, the via 147A is connected to the source/drain contact 145A, and the source/drain contact 145A is connected to the underlying source/drain regions 112 (not illustrated in FIG. 20B but illustrated in FIG. 20A) formed on the fin 90A. Similarly, the via 147B is connected to the gate structure 123A, and the conductive lines 149A and 149B are connected to vias 147C and 147D, respectively. In some embodiments, the conductive line 149A is configured to be connected to a reference voltage (e.g., electrical ground VSS), and the conductive line 149B is configured to be connected a supply voltage (e.g., a voltage signal VDD).

Recall that in FIGS. 19A and 19B, the dielectric structure 141 is embedded in the gate structure 123A at a location directly overlying the fin 90B, and therefore, no NSFET is formed at the location where the dielectric structure 141 intersects the fin 90B, which results in seven (instead of eight) NSFETs being formed in the region 106 of FIG. 19A. Therefore, in FIG. 20B, the gate structure 123A is shown to overlap the fin 90A but not the fin 90B. As a result, the source/drain contact 145D in FIG. 20B may be considered as a dummy source/drain contact (e.g., electrically isolated). In some embodiments, the source/drain contact 145D is omitted.

FIG. 21 is the equivalent circuit diagram of FIG. 20B, which shows a 7T SRAM memory cell. In FIG. 21, the p-type transistors 171, 173, 175, and 177 correspond to the p-type NSFETs denoted as WPG1, PU1, PU2, and WPG2 in FIG. 19A, respectively, and the n-type transistors 161, 163, and 165 correspond to the n-type NSFETs denoted as PD1, PD2, and RPG in FIG. 19A, respectively. The electrical connections between the seven transistors shown in FIG. 21 correspond to the electrical connections shown in FIG. 20B. The transistors 171, 173, 175, and 177 may be referred to as a first write pass-gate (WPG) transistor, a first pull-up (PU) transistor, a second PU transistor, and a second WPG transistor. The transistors 161, 163, and 165 may be referred to as a first pull-down (PD) transistor, a second PD transistor, and a read pass-gate (RPG) transistor.

The 7T SRAM memory cell in FIG. 21 comprises two cross-coupled inverters formed by four transistors: PU1, PU2, PD1, and PD2. These inverters are connected to form a latch that stores the data bit. The 7T memory cell is powered by the VDD supply voltage. Two access transistors, WPG1 and WPG2, are connected to the inverters via the source terminals of the access transistors. The gate terminals of the access transistors WPG1 and WPG2 are configured to be connected to a write word line (WWL) signal. The drain terminals of the access transistors WPG1 and WPG2 are configured to be connected to a write bit line bar (WBLB) signal and a write bit line (WBL) signal, respectively. The WWL, WBLB, and WBL signals control the write operation of the 7T memory cell. An additional read transistor RGP is connected to the storage node of one of the inverters through its source terminal. The gate terminal and the drain terminal of the read transistor RGP are configured to be connected to a read word line (RWL) signal and a read bit line (RBL) signal, respectively. The RWL signal and the RBL signal controls the read operation of the 7T memory cell. The presence of the additional read transistor RPG allows for separate read and write paths, which can help improve the 7T memory cell's stability and reduce read disturbances compared to a standard 6T SRAM cell.

Advantages are achieved by the disclosed embodiments. By using the DOI process and by forming the read transistor RPG on the n-type fin 90B (which provides stronger driving current due to its wider width W2), the 7T memory cell disclosed herein achieves strong read capability (e.g., fast reading speed, less read error) while still achieving good writing capability (e.g., fast write speed, less write error). To appreciate the advantages, consider a reference 7T memory cell design, where the transistor WPG1, WPG2, PD1, and PD2 are formed as n-type NSFETs over the n-type fin 90B, and the transistors PU1, PU2, and RGP are formed as p-type NSFETs over the p-type fin 90A. In addition, the NSFETs in the reference 7T memory cell are not formed using the DOI process, and instead, are formed using the traditional methods where one of the semiconductor materials (e.g., 52) in the layer stack 92 is selectively removed to release the other semiconductor material (e.g., 54) to form nanostructures 54. The reference 7T memory cell may be used for designs where write capability is the design priority to ensure fast write speed and low write error probability. Therefore, the transistors related with writing operation (e.g., WPG1 and WPG2) in the reference 7T memory cell are formed over the n-type fin 90B to provide strong driving current for the write operation, and the transistor related with reading operation (e.g., RPG) is formed over the p-type fin 90A. Since the p-type fin 90A has a smaller width, and since the intermixing issue causes dumbbell shaped nanostructures 54 (which has narrowed center portion, higher electrical resistance and smaller driving current), the reading capability of the reference 7T memory cell may not be ideal. For designs where the design priority is read capability, simply modifying the reference 7T memory cell design (e.g., by forming the transistors WPG1, WPG2, PU1, and PU2 over the p-type fin 90A and forming the transistors PD1, PD2, and RPG over the n-type fin 90B) may not achieve performance requirements for write capability because of the limited driving current for the write operation. The currently disclosed embodiments, by using the DOI process, avoids the issue caused by intermixing of the germanium and silicon, and the resulting channel regions 54 have rectangular cross-sections (instead of dumbbell shaped cross-sections) to provide improved driving current for the write operation. For example, a 20% improvement in the driving current is achieved by the channel regions 54 formed over the fin 90A, due to the use of the DOI process. Such significant improvement allows the disclosed embodiments to prioritize the read capability (e.g., by forming the read transistor RGP over the n-type fin 90B) while still achieving good write capability (e.g., by forming the write transistors WPG1 and WPG2 over the p-type fin 90A).

Additional processing may be performed to complete the fabrication of the NSFET device 100, as skilled artisans readily appreciate. For example, external connectors (e.g., copper pillars, conductive bumps) may be formed to be electrically coupled to the interconnect structure 155. Dicing may be performed to separate multiple NSFET devices into separate individual devices. Details are not discussed here.

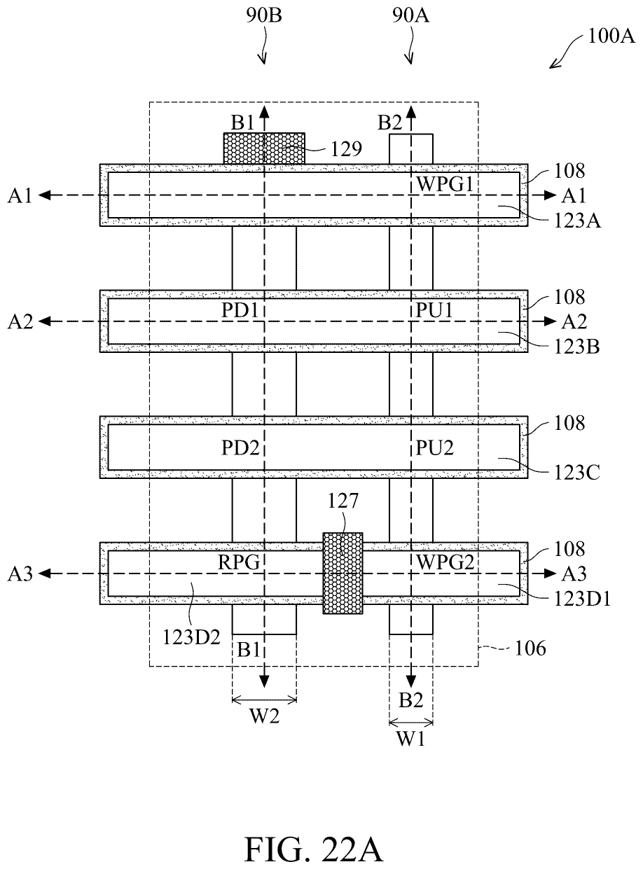

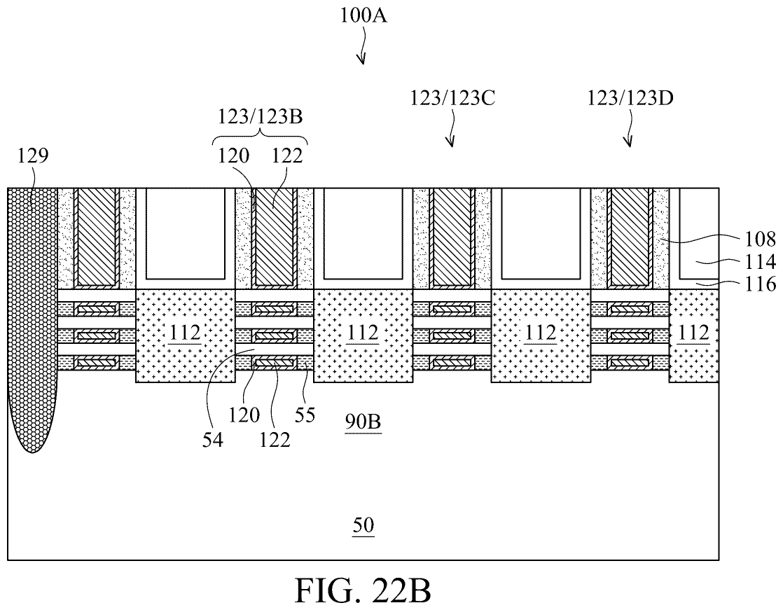

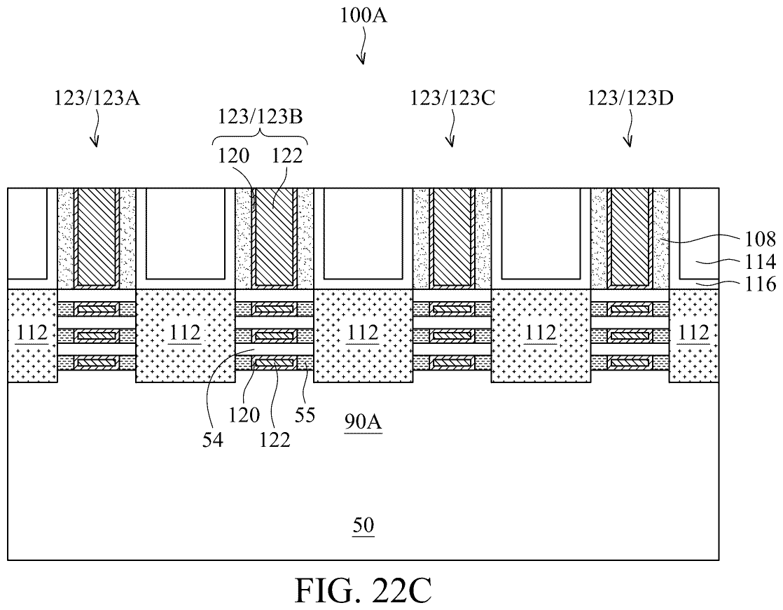

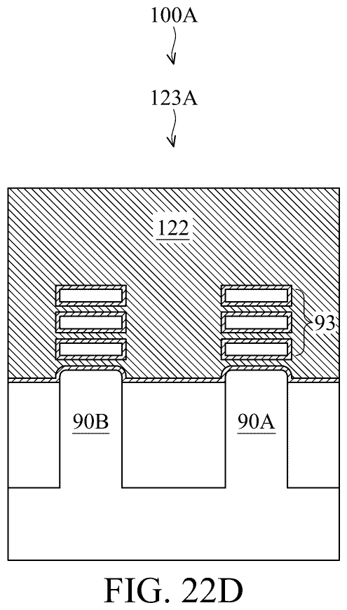

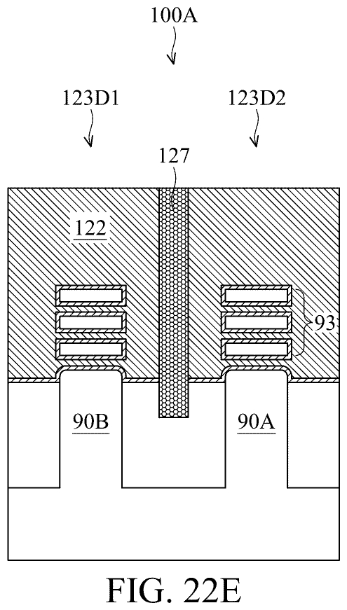

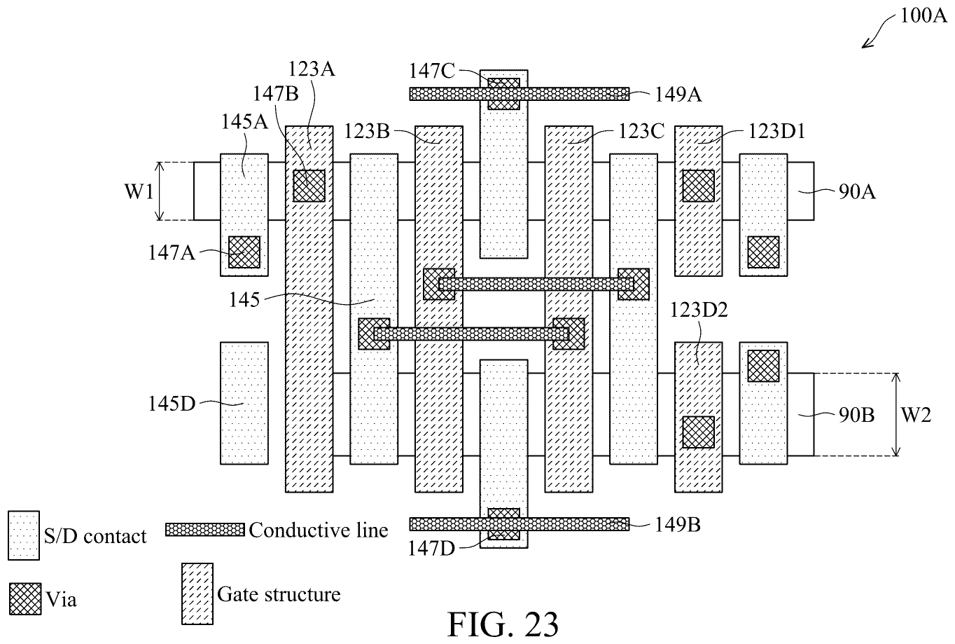

FIGS. 22A-22E and 23 are various views of a nanostructure field-effect transistor (NSFET) device 100A at various stages of manufacturing, in accordance with another embodiment. The NSFET device 100A is similar to the NSFET device 100, but omitting the dielectric structure 141. In addition, a portion of the fin 90B, together with the source/drain region 112 and nanostructures 54 overlying the portion of the fin 90B, are removed, in order to form the seven NSFETs of the 7T memory cell.

In an embodiment, to form the NSFET device 100A, the processing illustrated in FIGS. 2, 3A, 3B, 4A, 4B, 5A-5C, 6A-6C, 7A-7C, 8A-8C, 9A-9C, 10A-10C, and 11A-11C are performed to form the fins 90A, 90B, and the dummy gates 102A, 102B, 102C, and 102D over the fins 90A and 90B. Next, the dummy gates 102A, 102B, 102C, and 102D and the dummy gate dielectric 97 underlying these dummy gates are replaced by replacement gate structures 123A, 123B, 123C, and 123D, respectively, by performing the replacement gate process described above.

Next, as illustrated in FIGS. 22A-22E, the dielectric plug 127 is formed between the fin 90A and the fin 90B to cut (e.g. separate) the gate structures 123D into two separate gate structures 123D1 and 123D2. In addition, a portion of the fin 90B, which is disposed at a side of the gate structure 123A facing away from the gate structure 123B, together with the source/drain region 112 and nanostructures 54 overlying the portion of the fin 90B, are removed and replaced by a dielectric structure 129. FIG. 22A illustrates the top view of the NSFET device 100A. FIGS. 22B, 22C, 22D, and 22E illustrate the cross-sectional views along cross-sections B1-B1, B2-B2, A1-A1, and A3-A3 of FIG. 22A, respectively.

In some embodiments, to form the dielectric structure 129, a patterned mask layer is formed over the gate structures 123 and the first ILD 114, where an opening of the patterned mask layer overlies the portion of the fin 90B to be removed. Next, one or more anisotropic etching processes are performed to remove the source/drain region 112, the nanostructures 54, and the portion of the fin 90B underlying the opening. The opening may be extended by the one or more anisotropic etching processes into the substrate 50. Next, one or more layers of dielectric materials, such as silicon oxide, silicon nitride, a low-k dielectric material, or the like, are formed in the opening to fill the opening. A planarization process, such as CMP, may be performed to remove excess portions of the one or more layers of dielectric materials from the top surface of the first ILD 114. The remaining portion of the one or more layers of dielectric materials in the opening form the dielectric structure 129. The removal of the source/drain region 112 under the opening of the patterned mask layer effectively removes one NSFET from the region 106 of FIG. 22A, and therefore, a total of seven transistors are formed in the region 106 of FIG. 22A to form the 7T memory cell.

Next, the second ILD 151, the source/drain contacts 145S, the gate contacts 145G, and the interconnect structure 155 are formed over the first ILD 114, using the same or similar formation process as illustrated in FIG. 20A. The interconnect structure 155 interconnects the electrical components formed in/over the substrate 50 to form functional circuits (e.g., 7T memory cell). A top view of the NSFET device 100A is shown in FIG. 23.

FIG. 23 is similar to FIG. 20B, but the gate structure 123A overlaps (e.g., intersects) fins 90A and 90B. In addition, the fin 90B is shorter than the fin 90A, due to the removal of the portion of the fin 90B (and the nanostructures 54 and the source/drain region 112 overlying the portion of the fin 90B) as discussed above. Therefore, although the gate structure 123A overlaps both fins 90A and 90B, only one NSFET is formed at the location where the gate structure 123A overlaps the fin 90A. FIG. 23 shows a source/drain contact 145D formed over the location of the removed source/drain region 112. The source/drain contact 145D is a dummy source/drain contact (e.g., electrically isolated) because the source/drain region 112 under it is removed. The source/drain contact 145D may be omitted in some embodiments. The equivalent circuit diagram of the NSFET device 100A of FIG. 23 is the same as the circuit diagram in FIG. 21.

Advantages are achieved by the disclosed embodiments. For example, the use of the DOI process reduces intermixing between germanium and silicon, and provides significantly higher etching selectivity (e.g., >10000) between the disposable material 57 and the second semiconductor material 54. As a result, when the second semiconductor material 54 is released to form channel regions 54, the dimension of the channel regions 54 are preserved (e.g., little to no loss of channel width), thus providing improved driving current and lower channel resistance. In addition, by using the DOI process and by forming the read transistor RPG on the n-type fin 90B (which provides stronger driving current due to its wider width W2), the 7T memory cell disclosed herein achieves strong read capability (e.g., fast reading speed, less read error) while still achieving good writing capability (e.g., fast write speed, less write error).

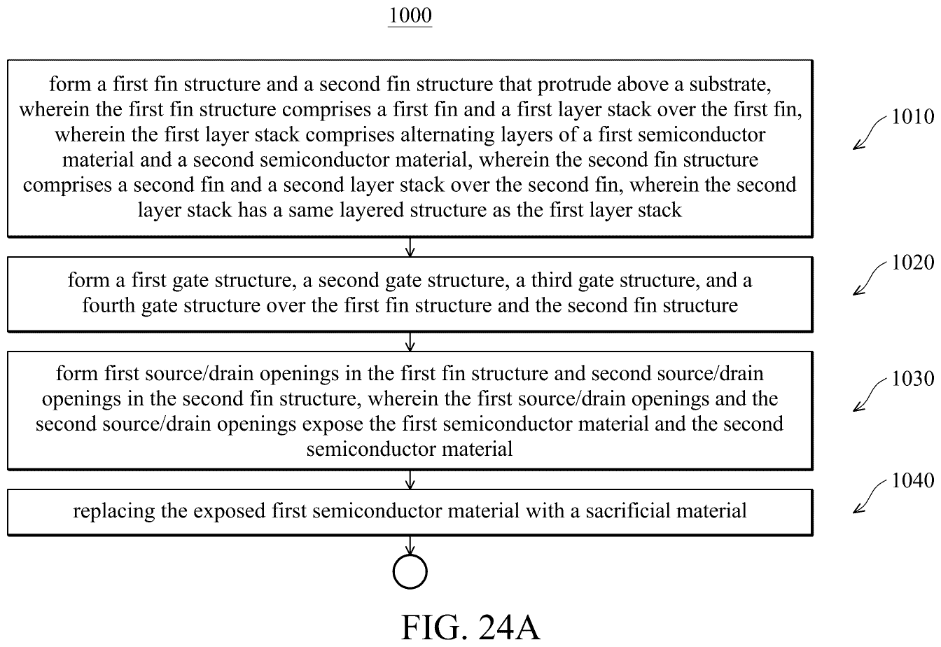

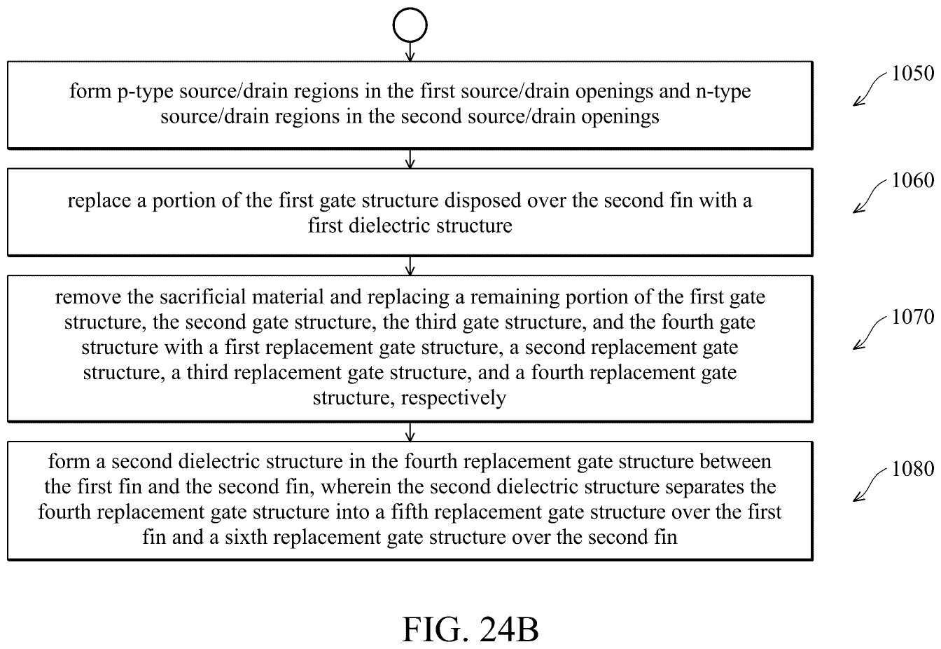

FIGS. 24A and 24B together illustrate a flow chart of a method 1000 of forming a seven-transistor (7T) memory cell of a semiconductor device, in accordance with some embodiments. It should be understood that the embodiment method shown in FIGS. 24A and 24B is merely an example of many possible embodiment methods. One of ordinary skill in the art would recognize many variations, alternatives, and modifications. For example, various steps as illustrated in FIGS. 24A and 24B may be added, removed, replaced, rearranged, or repeated.

Referring to FIGS. 24A and 24B, at block 1010, a first fin structure and a second fin structure that protrude above a substrate are formed, wherein the first fin structure comprises a first fin and a first layer stack over the first fin, wherein the first layer stack comprises alternating layers of a first semiconductor material and a second semiconductor material, wherein the second fin structure comprises a second fin and a second layer stack over the second fin, wherein the second layer stack has a same layered structure as the first layer stack. At block 1020, a first gate structure, a second gate structure, a third gate structure, and a fourth gate structure are formed over the first fin structure and the second fin structure. At block 1030, first source/drain openings are formed in the first fin structure and second source/drain openings are formed in the second fin structure, wherein the first source/drain openings and the second source/drain openings expose the first semiconductor material and the second semiconductor material. At block 1040, the exposed first semiconductor material is replaced with a sacrificial material. At block 1050, after replacing the exposed first semiconductor material, p-type source/drain regions are formed in the first source/drain openings and n-type source/drain regions are formed in the second source/drain openings. At block 1060, after forming the p-type source/drain regions and the n-type source/drain regions, a portion of the first gate structure disposed over the second fin is replaced with a first dielectric structure. At block 1070, after replacing the portion of the first gate structure, the sacrificial material is removed and a remaining portion of the first gate structure, the second gate structure, the third gate structure, and the fourth gate structure are replaced with a first replacement gate structure, a second replacement gate structure, a third replacement gate structure, and a fourth replacement gate structure, respectively. At block 1080, a second dielectric structure is formed in the fourth replacement gate structure between the first fin and the second fin, wherein the second dielectric structure separates the fourth replacement gate structure into a fifth replacement gate structure over the first fin and a sixth replacement gate structure over the second fin.

In an embodiment, a method of forming a seven-transistor (7T) memory cell of a semiconductor device includes: forming a first fin structure and a second fin structure that protrude above a substrate, wherein the first fin structure comprises a first fin and a first layer stack over the first fin, wherein the first layer stack comprises alternating layers of a first semiconductor material and a second semiconductor material, wherein the second fin structure comprises a second fin and a second layer stack over the second fin, wherein the second layer stack has a same layered structure as the first layer stack; forming a first gate structure, a second gate structure, a third gate structure, and a fourth gate structure over the first fin structure and the second fin structure; forming first source/drain openings in the first fin structure and second source/drain openings in the second fin structure, wherein the first source/drain openings and the second source/drain openings expose the first semiconductor material and the second semiconductor material; replacing the exposed first semiconductor material with a sacrificial material; forming p-type source/drain regions in the first source/drain openings and n-type source/drain regions in the second source/drain openings; replacing a portion of the first gate structure disposed over the second fin with a first dielectric structure; removing the sacrificial material and replacing a remaining portion of the first gate structure, the second gate structure, the third gate structure, and the fourth gate structure with a first replacement gate structure, a second replacement gate structure, a third replacement gate structure, and a fourth replacement gate structure, respectively; and forming a second dielectric structure in the fourth replacement gate structure between the first fin and the second fin, wherein the second dielectric structure separates the fourth replacement gate structure into a fifth replacement gate structure over the first fin and a sixth replacement gate structure over the second fin. In an embodiment, removing the sacrificial material and replacing the remaining portion of the first gate structure, the second gate structure, the third gate structure, and the fourth gate structure comprises: removing the remaining portion of the first gate structure, the second gate structure, the third gate structure, and the fourth gate structure to expose the sacrificial material and the second semiconductor material; selectively removing the exposed sacrificial material, wherein after the selectively removing, the second semiconductor material remain to form channel regions of the 7T memory cell; forming a gate dielectric material around the channel regions; and forming a gate electrode material around the gate dielectric material. In an embodiment, replacing the exposed first semiconductor material comprises: selectively removing the first semiconductor material to form gaps between the layers of the second semiconductor material; forming the sacrificial material in the first source/drain openings and the second source/drain openings, wherein the sacrificial material fills the gaps; and performing an anisotropic etching process to remove portions of the sacrificial material disposed outside the gaps. In an embodiment, the sacrificial material is formed of silicon oxide, silicon oxynitride, or aluminum oxide. In an embodiment, the method further comprises, after replacing the exposed first semiconductor material with the sacrificial material and before forming the p-type source/drain regions and the n-type source/drain regions: removing portions of the sacrificial material exposed by the first source/drain openings and the second source/drain openings to form sidewall recesses in the sacrificial material; and forming inner spacers in the sidewall recesses. In an embodiment, replacing the portion of the first gate structure comprises: forming a first dielectric plug and a second dielectric plug in the first gate structure on opposing sides of the second fin, wherein the portion of the first gate structure is interposed between the first dielectric plug and the second dielectric plug; after forming the first dielectric plug and the second dielectric plug, forming a first recess in the first gate structure by removing the portion of the first gate structure and removing portions of the sacrificial material and the second semiconductor material under the portion of the first gate structure; and filling the first recess with a first dielectric material to form the first dielectric structure. In an embodiment, forming the first recess comprises: forming a patterned mask layer over the first gate structure, wherein an opening of the patterned mask layer exposes the portion of the first gate structure; forming a first etching process to remove the portion of the first gate structure; and after the first etching process is finished, performing a second etching process different from the first etching process to remove the portions of the sacrificial material and the second semiconductor material under the portion of the first gate structure. In an embodiment, the first etching process is a wet etching process, and the second etching process is a dry etching process. In an embodiment, forming the second dielectric structure comprises: forming a second recess in the fourth replacement gate structure between the first fin and the second fin; and filling the second recess with a second dielectric material to form the second dielectric structure. In an embodiment, the first replacement gate structure is disposed over the first fin, wherein the method further comprises: forming a first write pass-gate (WPG) transistor of the 7T memory cell at a location where the first replacement gate structure intersects the first fin, wherein the first WPG transistor comprises the first replacement gate structure and respective p-type source/drain regions on opposing sides of the first replacement gate structure; forming a second WPG transistor of the 7T memory cell at a location where the fifth replacement gate structure intersects the first fin, wherein the second WPG transistor comprises the fifth replacement gate structure and respective p-type source/drain regions on opposing sides of the fifth replacement gate structure; and forming a read pass-gate (RPG) transistor of the 7T memory cell at a location where the sixth replacement gate structure intersects the second fin, wherein the RPG transistor comprises the sixth replacement gate structure and respective n-type source/drain regions on opposing sides of the sixth replacement gate structure. In an embodiment, a first portion of the second replacement gate structure is disposed over the first fin and a second portion of the second replacement gate structure is disposed over the second fin, wherein the method further comprises: forming a first pull-up (PU) transistor of the 7T memory cell at a location where the second replacement gate structure intersects the first fin, wherein the first PU transistor comprises the first portion of the second replacement gate structure and respective p-type source/drain regions on opposing sides of the first portion of the second replacement gate structure; and forming a first pull-down (PD) transistor of the 7T memory cell at a location where the second replacement gate structure intersects the second fin, wherein the first PD transistor comprises the second portion of the second replacement gate structure and respective n-type source/drain regions on opposing sides of the second portion of the second replacement gate structure. In an embodiment, a first portion of the third replacement gate structure is disposed over the first fin and a second portion of the third replacement gate structure is disposed over the second fin, wherein the method further comprises: forming a second PU transistor of the 7T memory cell at a location where the third replacement gate structure intersects the first fin, wherein the second PU transistor comprises the first portion of the third replacement gate structure and respective p-type source/drain regions on opposing sides of the first portion of the third replacement gate structure; and forming a second PD transistor of the 7T memory cell at a location where the third replacement gate structure intersects the second fin, wherein the second PD transistor comprises the second portion of the third replacement gate structure and respective n-type source/drain regions on opposing sides of the second portion of the third replacement gate structure.

In an embodiment, a method of forming a seven-transistor (7T) memory cell of a semiconductor device includes: forming a first fin structure and a second fin structure that protrude above a substrate, wherein the first fin structure comprises a first fin and a first layer stack over the first fin, wherein the first layer stack comprises alternating layers of a first semiconductor material and a second semiconductor material, wherein the second fin structure comprises a second fin and a second layer stack over the second fin, wherein the second layer stack has a same layered structure as the first layer stack; forming a first gate structure, a second gate structure, a third gate structure, and a fourth gate structure over the first fin structure and the second fin structure, wherein the second gate structure and the third gate structure are between the first gate structure and the fourth gate structure; forming first source/drain openings in the first fin structure and second source/drain openings in the second fin structure, wherein the first source/drain openings and the second source/drain openings expose the first semiconductor material and the second semiconductor material; replacing the exposed first semiconductor material with a sacrificial material; after replacing the exposed first semiconductor material, forming p-type source/drain regions in the first source/drain openings and n-type source/drain regions in the second source/drain openings; after forming the p-type source/drain regions and the n-type source/drain regions, removing the sacrificial material and replacing the first gate structure, the second gate structure, the third gate structure, and the fourth gate structure with a first replacement gate structure, a second replacement gate structure, a third replacement gate structure, and a fourth replacement gate structure, respectively; replacing a first n-type source/drain region of the n-type source/drain regions with a first dielectric structure, wherein the first n-type source/drain region is disposed at a first side of the first replacement gate structure facing away from the second replacement gate structure; and forming a second dielectric structure in the fourth replacement gate structure between the first fin and the second fin, wherein the second dielectric structure separates the fourth replacement gate structure into a fifth replacement gate structure over the first fin and a sixth replacement gate structure over the second fin. In an embodiment, removing the sacrificial material and replacing the first gate structure, the second gate structure, the third gate structure, and the fourth gate structure comprises: removing the first gate structure, the second gate structure, the third gate structure, and the fourth gate structure to expose the sacrificial material and the second semiconductor material; selectively removing the exposed sacrificial material, wherein after the selectively removing, the second semiconductor material remain to form channel regions of the 7T memory cell; forming a gate dielectric material around the channel regions; and forming a gate electrode material around the gate dielectric material. In an embodiment, replacing the first n-type source/drain region comprises: forming a patterned mask layer over the first replacement gate structure, wherein an opening of the patterned mask layer is at the first side of the first gate structure and overlies the first n-type source/drain region; performing one or more etching processes using the patterned mask layer as an etching mask, wherein the one or more etching processes remove the first n-type source/drain region and form a recess that extends into the second fin; and filling the recess with a dielectric material. In an embodiment, the first replacement gate structure, the second replacement gate structure, the third replacement gate structure, and the fifth replacement gate structure intersect the first fin at a first location, a second location, a third location, and a fourth location, respectively, wherein the method further comprises forming a first write pass-gate (WPG) transistor, a first pull-up (PU) transistor, a second PU transistor, and a second WPG transistor of the 7T memory cell at the first location, the second location, the third location, and the fourth location, respectively. In an embodiment, the second replacement gate structure, the third replacement gate structure, and the sixth replacement gate structure intersect the second fin at a fifth location, a sixth location, and a seventh location, respectively, wherein the method further comprises forming a first pull-down (PD) transistor, a second PD transistor, and a read pass-gate (RPG) transistor of the 7T memory cell at the fifth location, the sixth location, and the seven location, respectively.

In an embodiment, a memory device includes: a substrate; and a seven-transistor (7T) memory cell comprising: a first fin and a second fin that extend above the substrate, wherein the first fin is narrower than the second fin; a first gate structure, a second gate structure, a third gate structure, a fourth gate structure, and a fifth gate structure, wherein the second gate structure and the third gate structure are between the first gate structure and the fourth gate structure, wherein the fourth gate structure and the fifth gate structure extend along a same line, wherein in a top view, the first gate structure and the fourth gate structure overlap the first fin, the second gate structure and the third gate structure overlap the first fin and the second fin, and the fifth gate structure overlaps the second fin; p-type source/drain regions over the first fin and on opposing sides of the first gate structure, the second gate structure, the third gate structure, and the fourth gate structure; and n-type source/drain regions over the second fin and on opposing sides of the second gate structure, the third gate structure, and the fifth gate structure. In an embodiment, the memory device further comprises: first channel regions over the first fin and between respective ones of the p-type source/drain regions; and second channel regions over the second fin and between respective ones of the n-type source/drain regions, wherein the first gate structure, a first portion of the second gate structure, a first portion of the third gate structure, and the fourth gate structure surround respective ones of the first channel regions, wherein a second portion of the second gate structure, a second portion of the third gate structure, and the fifth gate structure surround respective ones of the second channel regions. In an embodiment, the first channel regions and the second channel regions are of a same semiconductor material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a seven-transistor (7T) memory cell of a semiconductor device, the method comprising:
forming a first fin structure and a second fin structure that protrude above a substrate, wherein the first fin structure comprises a first fin and a first layer stack over the first fin, wherein the first layer stack comprises alternating layers of a first semiconductor material and a second semiconductor material, wherein the second fin structure comprises a second fin and a second layer stack over the second fin, wherein the second layer stack has a same layered structure as the first layer stack;
forming a first gate structure, a second gate structure, a third gate structure, and a fourth gate structure over the first fin structure and the second fin structure;
forming first source/drain openings in the first fin structure and second source/drain openings in the second fin structure, wherein the first source/drain openings and the second source/drain openings expose the first semiconductor material and the second semiconductor material;
replacing the exposed first semiconductor material with a sacrificial material;
forming p-type source/drain regions in the first source/drain openings and n-type source/drain regions in the second source/drain openings;
replacing a portion of the first gate structure disposed over the second fin with a first dielectric structure;
removing the sacrificial material and replacing a remaining portion of the first gate structure, the second gate structure, the third gate structure, and the fourth gate structure with a first replacement gate structure, a second replacement gate structure, a third replacement gate structure, and a fourth replacement gate structure, respectively; and
forming a second dielectric structure in the fourth replacement gate structure between the first fin and the second fin, wherein the second dielectric structure separates the fourth replacement gate structure into a fifth replacement gate structure over the first fin and a sixth replacement gate structure over the second fin.

2. The method of claim 1, wherein removing the sacrificial material and replacing the remaining portion of the first gate structure, the second gate structure, the third gate structure, and the fourth gate structure comprises:
removing the remaining portion of the first gate structure, the second gate structure, the third gate structure, and the fourth gate structure to expose the sacrificial material and the second semiconductor material;
selectively removing the exposed sacrificial material, wherein after the selectively removing, the second semiconductor material remain to form channel regions of the 7T memory cell;
forming a gate dielectric material around the channel regions; and
forming a gate electrode material around the gate dielectric material.

3. The method of claim 1, wherein replacing the exposed first semiconductor material comprises:
selectively removing the first semiconductor material to form gaps between the layers of the second semiconductor material;
forming the sacrificial material in the first source/drain openings and the second source/drain openings, wherein the sacrificial material fills the gaps; and
performing an anisotropic etching process to remove portions of the sacrificial material disposed outside the gaps.

4. The method of claim 3, wherein the sacrificial material is formed of silicon oxide, silicon oxynitride, or aluminum oxide.

5. The method of claim 1, further comprising, after replacing the exposed first semiconductor material with the sacrificial material and before forming the p-type source/drain regions and the n-type source/drain regions:
removing portions of the sacrificial material exposed by the first source/drain openings and the second source/drain openings to form sidewall recesses in the sacrificial material; and
forming inner spacers in the sidewall recesses.

6. The method of claim 1, wherein replacing the portion of the first gate structure comprises:
forming a first dielectric plug and a second dielectric plug in the first gate structure on opposing sides of the second fin, wherein the portion of the first gate structure is interposed between the first dielectric plug and the second dielectric plug;
after forming the first dielectric plug and the second dielectric plug, forming a first recess in the first gate structure by removing the portion of the first gate structure and removing portions of the sacrificial material and the second semiconductor material under the portion of the first gate structure; and
filling the first recess with a first dielectric material to form the first dielectric structure.

7. The method of claim 6, wherein forming the first recess comprises:
forming a patterned mask layer over the first gate structure, wherein an opening of the patterned mask layer exposes the portion of the first gate structure;
forming a first etching process to remove the portion of the first gate structure; and
after the first etching process is finished, performing a second etching process different from the first etching process to remove the portions of the sacrificial material and the second semiconductor material under the portion of the first gate structure.

8. The method of claim 7, wherein the first etching process is a wet etching process, and the second etching process is a dry etching process.

9. The method of claim 6, wherein forming the second dielectric structure comprises:
forming a second recess in the fourth replacement gate structure between the first fin and the second fin; and
filling the second recess with a second dielectric material to form the second dielectric structure.

10. The method of claim 1, wherein the first replacement gate structure is disposed over the first fin, wherein the method further comprises:
forming a first write pass-gate (WPG) transistor of the 7T memory cell at a location where the first replacement gate structure intersects the first fin, wherein the first WPG transistor comprises the first replacement gate structure and respective p-type source/drain regions on opposing sides of the first replacement gate structure;
forming a second WPG transistor of the 7T memory cell at a location where the fifth replacement gate structure intersects the first fin, wherein the second WPG transistor comprises the fifth replacement gate structure and respective p-type source/drain regions on opposing sides of the fifth replacement gate structure; and
forming a read pass-gate (RPG) transistor of the 7T memory cell at a location where the sixth replacement gate structure intersects the second fin, wherein the RPG transistor comprises the sixth replacement gate structure and respective n-type source/drain regions on opposing sides of the sixth replacement gate structure.

11. The method of claim 10, wherein a first portion of the second replacement gate structure is disposed over the first fin and a second portion of the second replacement gate structure is disposed over the second fin, wherein the method further comprises:
forming a first pull-up (PU) transistor of the 7T memory cell at a location where the second replacement gate structure intersects the first fin, wherein the first PU transistor comprises the first portion of the second replacement gate structure and respective p-type source/drain regions on opposing sides of the first portion of the second replacement gate structure; and
forming a first pull-down (PD) transistor of the 7T memory cell at a location where the second replacement gate structure intersects the second fin, wherein the first PD transistor comprises the second portion of the second replacement gate structure and respective n-type source/drain regions on opposing sides of the second portion of the second replacement gate structure.

12. The method of claim 11, wherein a first portion of the third replacement gate structure is disposed over the first fin and a second portion of the third replacement gate structure is disposed over the second fin, wherein the method further comprises:
forming a second PU transistor of the 7T memory cell at a location where the third replacement gate structure intersects the first fin, wherein the second PU transistor comprises the first portion of the third replacement gate structure and respective p-type source/drain regions on opposing sides of the first portion of the third replacement gate structure; and
forming a second PD transistor of the 7T memory cell at a location where the third replacement gate structure intersects the second fin, wherein the second PD transistor comprises the second portion of the third replacement gate structure and respective n-type source/drain regions on opposing sides of the second portion of the third replacement gate structure.

13. A method of forming a seven-transistor (7T) memory cell of a semiconductor device, the method comprising:
forming a first fin structure and a second fin structure that protrude above a substrate, wherein the first fin structure comprises a first fin and a first layer stack over the first fin, wherein the first layer stack comprises alternating layers of a first semiconductor material and a second semiconductor material, wherein the second fin structure comprises a second fin and a second layer stack over the second fin, wherein the second layer stack has a same layered structure as the first layer stack;
forming a first gate structure, a second gate structure, a third gate structure, and a fourth gate structure over the first fin structure and the second fin structure, wherein the second gate structure and the third gate structure are between the first gate structure and the fourth gate structure;
forming first source/drain openings in the first fin structure and second source/drain openings in the second fin structure, wherein the first source/drain openings and the second source/drain openings expose the first semiconductor material and the second semiconductor material;
replacing the exposed first semiconductor material with a sacrificial material;
after replacing the exposed first semiconductor material, forming p-type source/drain regions in the first source/drain openings and n-type source/drain regions in the second source/drain openings;
after forming the p-type source/drain regions and the n-type source/drain regions, removing the sacrificial material and replacing the first gate structure, the second gate structure, the third gate structure, and the fourth gate structure with a first replacement gate structure, a second replacement gate structure, a third replacement gate structure, and a fourth replacement gate structure, respectively;
replacing a first n-type source/drain region of the n-type source/drain regions with a first dielectric structure, wherein the first n-type source/drain region is disposed at a first side of the first replacement gate structure facing away from the second replacement gate structure; and
forming a second dielectric structure in the fourth replacement gate structure between the first fin and the second fin, wherein the second dielectric structure separates the fourth replacement gate structure into a fifth replacement gate structure over the first fin and a sixth replacement gate structure over the second fin.

14. The method of claim 13, wherein removing the sacrificial material and replacing the first gate structure, the second gate structure, the third gate structure, and the fourth gate structure comprises:
removing the first gate structure, the second gate structure, the third gate structure, and the fourth gate structure to expose the sacrificial material and the second semiconductor material;
selectively removing the exposed sacrificial material, wherein after the selectively removing, the second semiconductor material remain to form channel regions of the 7T memory cell;
forming a gate dielectric material around the channel regions; and
forming a gate electrode material around the gate dielectric material.

15. The method of claim 13, wherein replacing the first n-type source/drain region comprises:
forming a patterned mask layer over the first replacement gate structure, wherein an opening of the patterned mask layer is at the first side of the first gate structure and overlies the first n-type source/drain region;
performing one or more etching processes using the patterned mask layer as an etching mask, wherein the one or more etching processes remove the first n-type source/drain region and form a recess that extends into the second fin; and
filling the recess with a dielectric material.

16. The method of claim 13, wherein the first replacement gate structure, the second replacement gate structure, the third replacement gate structure, and the fifth replacement gate structure intersect the first fin at a first location, a second location, a third location, and a fourth location, respectively, wherein the method further comprises forming a first write pass-gate (WPG) transistor, a first pull-up (PU) transistor, a second PU transistor, and a second WPG transistor of the 7T memory cell at the first location, the second location, the third location, and the fourth location, respectively.

17. The method of claim 16, wherein the second replacement gate structure, the third replacement gate structure, and the sixth replacement gate structure intersect the second fin at a fifth location, a sixth location, and a seventh location, respectively, wherein the method further comprises forming a first pull-down (PD) transistor, a second PD transistor, and a read pass-gate (RPG) transistor of the 7T memory cell at the fifth location, the sixth location, and the seven location, respectively.

18. A memory device comprising:
a substrate; and
a seven-transistor (7T) memory cell comprising:
a first fin and a second fin that extend above the substrate, wherein the first fin is narrower than the second fin;
a first gate structure, a second gate structure, a third gate structure, a fourth gate structure, and a fifth gate structure, wherein the second gate structure and the third gate structure are between the first gate structure and the fourth gate structure, wherein the fourth gate structure and the fifth gate structure extend along a same line, wherein in a top view, the first gate structure and the fourth gate structure overlap the first fin, the second gate structure and the third gate structure overlap the first fin and the second fin, and the fifth gate structure overlaps the second fin;
p-type source/drain regions over the first fin and on opposing sides of the first gate structure, the second gate structure, the third gate structure, and the fourth gate structure; and
n-type source/drain regions over the second fin and on opposing sides of the second gate structure, the third gate structure, and the fifth gate structure.

19. The memory device of claim 18, further comprising:
first channel regions over the first fin and between respective ones of the p-type source/drain regions; and
second channel regions over the second fin and between respective ones of the n-type source/drain regions, wherein the first gate structure, a first portion of the second gate structure, a first portion of the third gate structure, and the fourth gate structure surround respective ones of the first channel regions, wherein a second portion of the second gate structure, a second portion of the third gate structure, and the fifth gate structure surround respective ones of the second channel regions.

20. The memory device of claim 19, wherein the first channel regions and the second channel regions are of a same semiconductor material.
